(19) United States
(12) Patent Application Publication
(10) Pub. No.: US 2019/0181348 A1
(43) Pub. Date: Jun. 13, 2019

(54) BRANCH POINT EFFECT ON STRUCTURE AND ELECTRONIC PROPERTIES OF CONJUGATED POLYMERS

(71) Applicant: The Regents of the University of California, Oakland, CA (US)

(72) Inventors: Colin R. Bridges, Goleta, CA (US); Ming Wang, Goleta, CA (US); Michael J. Ford, Santa Barbara, CA (US); Guillermo C. Bazan, Santa Barbara, CA (US); Rachel A. Segalman, Santa Barbara, CA (US)

(21) Appl. No.: 16/144,512

(22) Filed: Sep. 27, 2018

Related U.S. Application Data
(60) Provisional application No. 62/563,865, filed on Sep. 27, 2017.

(51) Int. Cl. H01L 51/00

(52) U.S. Cl. CPC H01L 51/0036; H01L 51/0558; H01L 51/0043

(57) ABSTRACT

Synthesis of lyotropic semiconducting polymers having novel side chains enabling control over crystalline fraction, crystalline orientation, and the unit cell (specifically the π-stacking distance). Moving the branch point in the side chain further from the conjugated backbone not only retains the lyotropic liquid crystalline behavior as observed by UV-vis and POM, but also achieves reduced π-stacking distance. This results in higher charge carrier mobility, reaching (in one or more examples) a mobility of at least 0.41 cm²V⁻¹s⁻¹ when the polymers were non-aligned.

### CROSS REFERENCE TO RELATED APPLICATIONS

This application claims the benefit under 35 U.S.C. Section 119(e) of co-pending and commonly-assigned U.S. Provisional Patent Application No. 62/563,865, filed Sep. 27, 2017, by Colin Bridges and Rachel Segalman, entitled “BRANCH POINT EFFECT ON STRUCTURE AND ELECTRONIC PROPERTIES OF CONJUGATED POLYMERS,” Attorney's Docket No. 30794.661-US-P1 (2018-089);

which application is incorporated by reference herein.

This application is related to the following co-pending and commonly-assigned U.S. patent applications:

U.S. Utility application Ser. No. 15/661,442, filed Jul. 27, 2017, by Colin R. Bridges, Michael J. Ford, Guillermo C. Bazan, and Rachel A. Segalman, entitled “FORMATION AND STRUCTURE OF LYOTROPIC LIQUID CRYSTALLINE MESOPHASES IN DONOR-ACCEPTOR SEMICONDUCTING POLYMERS” which application claims the benefit under 35 U.S.C. Section 119(e) of Provisional Patent Application No. 62/367,401, filed Jul. 27, 2016, by Colin R. Bridges, Michael J. Ford, Guillermo C. Bazan, and Rachel A. Segalman, entitled “FORMATION AND STRUCTURE OF LYOTROPIC LIQUID CRYSTALLINE MESOPHASES IN DONOR-ACCEPTOR SEMICONDUCTING POLYMERS,” Attorney's Docket No., 30794.623-US-P1 (2017-036); and U.S. Provisional Patent Application No. 62/480,693 filed Apr. 3, 2017, by Colin Bridges and Rachel A. Segalman, entitled “MOLECULAR CONSIDERATIONS FOR MESOPHASE INTERACTION AND ALIGNMENT OF LYOTROPIC LIQUID CRYSTALLINE SEMICONDUCTING POLYMERS,” Attorney's Docket No. 30794.651-US-P1 (U.C. Ref. 2017-606-1);

U.S. Utility patent application Ser. No. 15/400,579, filed Jan. 6, 2017, by Michael J. Ford and Guillermo Bazan, entitled “STABLE ORGANIC FIELD-EFFECT TRANSISTORS BY INCORPORATING AN ELECTRON-ACCEPTING MOLECULE,” Attorney's Docket No., 30794.608-US-U1, which application claims the benefit under 35 U.S.C. Section 119(e) of U.S. Provisional Patent Application No. 62/276,145, filed Jan. 7, 2016, by Michael J. Ford and Guillermo Bazan, entitled “STABLE ORGANIC FIELD-EFFECT TRANSISTORS BY INCORPORATING AN ELECTRON-ACCEPTING MOLECULE,” Attorney's Docket No., 30794.608-US-P1;

U.S. Utility patent application Ser. No. 15/496,826, filed Apr. 25, 2017, by Guillermo Bazan and Ming Wang, entitled “NOVEL WEAK DONOR-ACCEPTOR CONJUGATED COPOLYMERS FOR FIELD-EFFECT TRANSISTOR APPLICATIONS,” Attorney's Docket No., 30794.616-US-U1, which application claims the benefit under 35 U.S.C. Section 119(e) of U.S. Provisional Patent Application No. 62/327,311, filed Apr. 25, 2016, by Guillermo C. Bazan and Ming Wang, entitled “NOVEL WEAK DONOR-ACCEPTOR CONJUGATED COPOLYMERS FOR FIELD-EFFECT TRANSISTOR APPLICATIONS,” Attorney's Docket No. 30794.616-US-P1 (2016-609); and U.S. Provisional Patent Application No. 62/489,303, filed Apr. 24, 2017, by Guillermo C. Bazan and Ming Wang, entitled “LINEAR CONJUGATED POLYMER BACKBONES IMPROVE THE ANISOTROPIC MORPHOLOGY IN NANOGROOVE ASSISTED ALIGNMENT ORGANIC FIELD-EFFECT TRANSISTOR APPLICATIONS,” Attorney's Docket No. 30794.616-US-P2 (2016-609), U.S. Provisional Patent Application No. 62/327,311, filed Apr. 25, 2016, by Guillermo Bazan and Ming Wang, entitled “NOVEL WEAK DONOR-ACCEPTOR CONJUGATED COPOLYMERS FOR FIELD-EFFECT TRANSISTOR APPLICATIONS,” Attorney's Docket No., 30794.616-US-P 1;

U.S. Utility patent application Ser. No. 15/599,816, filed May 19, 2017, by Michael J. Ford, Hengbin Wang, and Guillermo Bazan, entitled “ORGANIC SEMICONDUCTOR SOLUTION BLENDS FOR SWITCHING AMBIPOLAR TRANSPORT TO N-TYPE TRANSPORT,” Attorney's Docket No. 30794.619-US-P1 (2016-607), which application claims the benefit under 35 U.S.C. Section 119(e) of U.S. Provisional Patent Application No. 62/338,866, filed May 19, 2016, by Michael J. Ford, Hengbin Wang, and Guillermo Bazan, entitled “ORGANIC SEMICONDUCTOR SOLUTION BLENDS FOR SWITCHING AMBIPOLAR TRANSPORT TO N-TYPE TRANSPORT,” Attorney's Docket No. 30794.619-US-P1 (2016-607);

U.S. Utility patent application Ser. No. 15/349,920, filed Nov. 11, 2016, by Ming Wang and Guillermo Bazan, entitled “FLUORINE SUBSTITUTION INFLUENCE ON BENZO[2,1,3]THIODIAZOLE BASED POLYMERS FOR FIELD-EFFECT TRANSISTOR APPLICATIONS,” Attorney's Docket No., 30794.607-US-P1 (2016-316), which application claims the benefit under 35 U.S.C. Section 119(e) of U.S. Provisional Patent Application No. 62/253,975, filed Nov. 11, 2015, by Ming Wang and Guillermo Bazan, entitled “FLUORINE SUBSTITUTION INFLUENCE ON BENZO[2,1,3]THIODIAZOLE BASED POLYMERS FOR FIELD-EFFECT TRANSISTOR APPLICATIONS,” Attorney's Docket No., 30794.607-US-P1 (2016-316);

U.S. Utility patent application Ser. No. 15/349,920, filed Nov. 11, 2016, by Byoung Hoon Lee, Ben B. Y. Hsu, Chan Luo, Ming Wang, Guillermo Bazan, and Alan J. Heeger, entitled “SEMICONDUCTING POLYMERS WITH MOBILITY APPROACHING ONE HUNDRED SQUARE CENTIMETERS PER VOLT PER SECOND,” Attorney's Docket No. 30794.598-US-U1 (U.C. Ref 2016-239-1), which application claims the benefit under 35 U.S.C. Section 119(e) of U.S. Provisional Patent Application No. 62/263,058, filed Dec. 4, 2015, by Byoung Hoon Lee, Ben B. Y. Hsu, Chan Luo, Ming Wang, Guillermo Bazan, and Alan J. Heeger, entitled “SEMICONDUCTING POLYMERS WITH MOBILITY APPROACHING ONE HUNDRED SQUARE CENTIMETERS PER VOLT PER SECOND,” Attorney's Docket No. 30794.598-US-P1 (U.C. Ref 2016-239-1);

U.S. Utility patent application Ser. No. 15/256,160, filed Sep. 2, 2016, by Byoung Hoon Lee and Alan J. Heeger, entitled “DOPING-INDUCED CARRIER DENSITY MODULATION IN POLYMER FIELD-EFFECT TRANSISTORS,” Attorney's Docket No. 30794.595-US-P1 (U.C. Ref. 2016-115), which application claims the benefit under 35 U.S.C. Section 119(e) of co-pending and commonly-assigned U.S. Provisional Patent Application No. 62/214,076, filed Sep. 3, 2015, by Byoung Hoon Lee and Alan J. Heeger, entitled “DOPING-INDUCED CARRIER DENSITY MODULATION IN POLYMER FIELD-EFFECT TRANSISTORS,” Attorney's Docket No. 30794.595-US-P1 (U.C. Ref. 2016-115-1);

U.S. Utility patent application Ser. No. 15/241,949 filed Aug. 19, 2016, by Michael Ford and Guillermo Bazan, entitled “HIGH MOBILITY POLYMER ORGANIC FIELD-EFFECT TRANSISTORS BY BLADE-COATING SEMICONDUCTOR: INSULATOR BLEND SOLUTIONS,” Attorney's Docket No. 30794.592-US-U1 (U.C. Ref 2016-112), which application claims the benefit under 35 U.S.C. Section 119(e) of U.S. Provisional Patent Application No. 62/207,707, filed Aug. 20, 2015, by Michael Ford and Guillermo Bazan, entitled “HIGH MOBILITY POLYMER ORGANIC FIELD-EFFECT TRANSISTORS BY BLADE-COATING SEMICONDUCTOR: INSULATOR BLEND SOLUTIONS,” Attorney's Docket No. 30794.592-US-P1 (U.C. Ref. 2016-112-1); and U.S. Provisional Patent Application No. 62/262,025, filed Dec. 2, 2015, by Michael Ford and Guillermo Bazan, entitled “HIGH MOBILITY POLYMER ORGANIC FIELD-EFFECT TRANSISTORS BY BLADE-COATING SEMICONDUCTOR: INSULATOR BLEND SOLUTIONS,” Attorney's Docket No. 30794.592-US-P2 (U.C. Ref. 2016-112-2);

U.S. Utility application Ser. No. 15/213,029 filed on Jul. 18, 2016 by Byoung Hoon Lee and Alan J. Heeger, entitled “FLEXIBLE ORGANIC TRANSISTORS WITH CONTROLLED NANOMORPHOLOGY”, Attorney's Docket No. 30794.0589-US-U1 (UC Ref. 2015-977-1), which application claims the benefit under 35 U.S.C. Section 119(e) of U.S. Utility U.S. Provisional Application Ser. No. 62/193,909 filed on Jul. 17, 2015 by Byoung Hoon Lee and Alan J. Heeger, entitled “FLEXIBLE ORGANIC TRANSISTORS WITH CONTROLLED NANOMORPHOLOGY”, Attorney's Docket No. 30794.0589-US-P1 (UC Ref. 2015-977-1);

U.S. Utility patent application Ser. No. 15/058,994, filed Mar. 2, 2016, by Shrayesh N. Patel, Edward J. Kramer, Michael L. Chabinyc, Chan Luo and Alan J. Heeger, entitled “BLADE COATING ON NANOGROOVED SUBSTRATES YIELDING ALIGNED THIN FILMS OF HIGH MOBILITY SEMICONDUCTING POLYMERS,” Attorney's Docket No. 30794.583-US-P1 (U.C. Ref 2015-437), which Application claims the benefit under 35 U.S.C. Section 119(e) of U.S. Provisional Patent Application No. 62/127,116, filed Mar. 2, 2015, by Shrayesh N. Patel, Edward J. Kramer, Michael L. Chabinyc, Chan Luo and Alan J. Heeger, entitled “BLADE COATING ON NANOGROOVED SUBSTRATES YIELDING ALIGNED THIN FILMS OF HIGH MOBILITY SEMICONDUCTING POLYMERS,” Attorney's Docket No. 30794.583-US-P1 (U.C. Ref 2015-437);

U.S. Utility patent application Ser. No. 14/585,653, filed on Dec. 30, 2014, by Chan Luo and Alan Heeger, entitled “HIGH MOBILITY POLYMER THIN FILM TRANSISTORS WITH CAPILLARITY MEDIATED SELF-ASSEMBLY”, Attorney's Docket No. 30794.537-US-U1 (UC Ref 2014-337), which application claims the benefit under 35 U.S.C. Section 119(e) of co-pending U.S. Provisional Patent Application Ser. No. 61/923,452, filed on Jan. 3, 2014, entitled “HIGH MOBILITY POLYMER THIN FILM TRANSISTORS WITH CAPILLARITY MEDIATED SELF-ASSEMBLY,” Attorney's Docket No. 30794.537-US-P1 (UC Ref 2014-337);

U.S. Utility patent application Ser. No. 14/426,467, filed on Mar. 6, 2015, by Hsing-Rong Tseng, Lei Ying, Ben B. Y. Hsu, Christopher J. Takacs, and Guillermo C. Bazan, entitled “FIELD-EFFECT TRANSISTORS BASED ON MACROSCOPICALLY ORIENTED POLYMERS,” which application claims the benefit under 35 U.S.C. § 365 of PCT International patent application serial no. PCT/US13/058546 filed Sep. 6, 2013, which application claims the benefit under 35 U.S.C. Section 119(e) of co-pending U.S. Provisional Patent Application Ser. Nos. 61/698,065, filed on Sep. 7, 2012, and 61/863,255, filed on Aug. 7, 2013, entitled “FIELD-EFFECT TRANSISTORS BASED ON MACROSCOPICALLY ORIENTED POLYMERS,” (UC REF 2013-030); and

U.S. Utility patent application Ser. No. 13/526,371, filed on Jun. 18, 2012, by G. Bazan, L. Ying, B. Hsu, W. Wen, H-R Tseng, and G. Welch entitled “REGIOREGULAR PYRIDAL[2,1,3]THIADIAZOLE PI-CONJUGATED COPOLYMERS FOR ORGANIC SEMICONDUCTORS” (Attorney Docket No. 1279-543 and U.C. Docket No. 2011-577-3), which application claims priority under 35 U.S.C. § 119(e) to U.S. Provisional Patent Application Ser. No. 61/498,390, filed on Jun. 17, 2011, by G. Bazan, L. Ying, B. Hsu, and G. Welch entitled “REGIOREGULAR CONSTRUCTIONS FOR THE SYNTHESIS OF THIADIAZOLO (3,4) PYRIDINE CONTAINING NARROW BAND GAP CONJUGATED POLYMERS” (Attorney Docket No. 1279-543P and U.C. Docket No. 2011-577-1) and U.S. Provisional Patent Application Ser. No. 61/645,970, filed on May 11, 2012, by G. Bazan, L. Ying, and Wen, entitled “REGIOREGULAR PYRIDAL[2,1,3]THIADIAZOLE PI-CONJUGATED COPOLYMERS FOR ORGANIC SEMICONDUCTORS” (Attorney Docket No. 1279-543P2 and U.C. Docket No. 2011-577-2);

all of which applications are incorporated by reference herein.

### BACKGROUND OF THE INVENTION

### 1. Field of the Invention

This invention relates to method for fabricating organic devices using lyotropic semiconducting polymers and designing semiconducting polymer materials that exhibit liquid crystalline mesophases.

### 2. Description of the Related Art

(Note: This application references a number of different publications as indicated throughout the specification by one or more reference numbers in superscripts, e.g., ^{x}. A list of these different publications ordered according to these reference numbers can be found below in the section entitled “References.” Each of these publications is incorporated by reference herein.)

Semiconducting polymers exhibiting lyotropic liquid crystalline (LC) mesophases allow greater control over crystallinity and crystallite orientation simultaneously. ¹⁻⁸The ability to control molecular packing and orientation from the nano- to macro-scale is desirable for optimizing electronic devices fabricated using semiconducting polymers. ⁹⁻²²Lyotropic LC mesophases can be accessed in semiconducting polymers by taking advantage of the polarity difference between the solubilizing side chains and conjugated backbone, allowing polymers with highly branched side chains to form LC mesophases in non-polar solvents. ^{23, 24}However, introducing side chain branch points also increases the backbone π-stacking distance (due to steric repulsion from the side chain structure), which has a negative impact on the electronic properties and negates any improvements gained by achieving more favourable mesostructures.

The present disclosure reports on synthesis of novel side chains enabling lyotropic liquid crystalline mesophases with control over crystalline fraction and orientation, as well as superior control over the unit cell (specifically the π-stacking distance).

### SUMMARY OF THE INVENTION

Liquid crystalline materials allow for control over molecular orientation, a desirable property for polymer electronics. However, conventional lyotropic liquid crystalline materials that can be used for polymer electronics necessitate solubilizing side chains which disrupt molecular packing, resulting in poor charge carrier mobility.

The impact these structural changes have on mesostructures as well as electronic properties is explored herein. We also explore using rubbed polyimide as an alignment layer on top of which we fabricate OFETs as a facile method of providing ideal mesostructures for charge transport across large distances. This study establishes design rules guiding how the unit cell of lyotropic mesophases can be tuned by side chain modification, and how this affects charge carrier mobility in OFETs.

The present disclosure report on the discovery that moving the branch point in the side chain further from the conjugated backbone not only retains the lyotropic liquid crystalline behavior (as observed by Ultraviolet-visible (UV-vis) spectroscopy and polarized optical microscopy (POM)) but also achieves reduced π-stacking distance. In one or more examples, transistors fabricated using lyotropic LC semiconducting polymers achieve mobilities of at least 0.41 cm² V⁻¹s⁻¹.

As shown in the previous progress report, alignment of P2F on this substrate is very effective, as seen by polarized optical microscopy.

The semiconducting polymers can be embodied in many ways including, but not limited to, the following examples.

1. A composition of matter, comprising lyotropic semiconducting polymers each having a backbone and a side chain attached to the backbone, wherein the side chain includes a branched chain having a branching point positioned more than one atom from the backbone and along the side chain, the branching point is the first or closest branching point to the backbone.

2. The composition of matter of example 1, wherein the branching point is at a position along the side chain between 2 and 20 atoms from the backbone.

3. The composition of matter of one or any combination of the previous examples, wherein the atom on the side chain at the branching point is carbon or a heteroatom that is at least trivalent.

4. The composition of matter of one or any combination of the previous examples, further comprising a lyotropic solution including the lyotropic semiconducting polymers aligned in a liquid crystal.

5. The composition of matter of one or any combination of the previous examples, wherein the backbone comprises a donor-acceptor copolymer backbone including fused aromatic rings and fluorine.

6. The composition of matter of one or any combination of the previous examples, wherein the branched side chains disrupt pi stacking between the lyotropic semiconducting polymers, and the branched side chains extend outside a plane containing the fused aromatic rings.

The composition of matter of example 6, further comprising a pair of branched sidechains each bonded to the same carbon atom in the fused atomic rings, and each of the branched side chains in the pair extending on opposite sides of the plane at an angle in a range of 60-90 degrees with respect to the plane.

8. The composition of matter of example 6, wherein the branched side chains are oriented so as to disrupt pi stacking between the lyotropic semiconducting polymers, and positioning the branching point away from the backbone and along the side chain increases mobility of the lyotropic semiconducting polymer by a factor of at least 100.

9. The composition of matter of example 6, wherein positioning the branching point away from the backbone and along the side chain reduces a pi stacking distance between the lyotropic semiconducting polymers by at least 0.25 Å (e.g., the pi-pi stacking distance D is reduced by 0.25 Å as compared to using the unbranched side chain).

10. The composition of matter of one or any combination of the previous examples, wherein the semiconducting polymers are amphiphilic semiconducting polymers, and the side chains dissolve in a solvent more effectively than the backbone.

12. The composition of matter of example 10, wherein the solvent comprises at least one compound selected from an alkane, an alkene, an alkyne, an ether, an ester, an alcohol, a halide, an aldehyde, a ketone, an amine, an amide, and water.

13. The composition of matter of one or any combination of the previous examples, wherein the side chain is a branched C₅-C₅₀ alkyl chain.

14. The composition of matter of one or any combination of the previous examples, wherein the backbone has a repeat unit that comprises:

an acceptor of the structure:

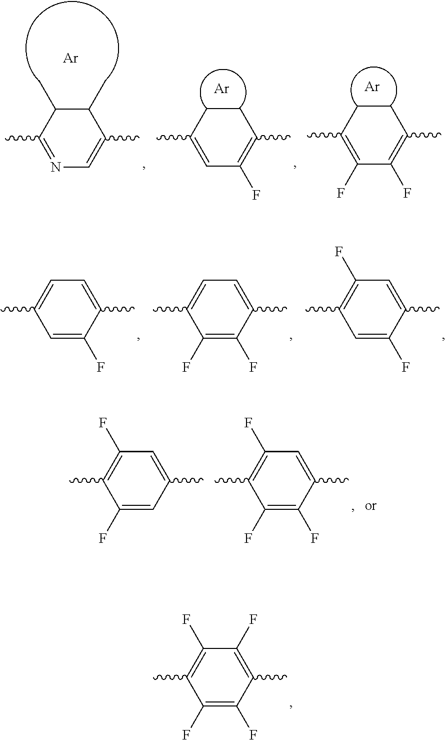

wherein Ar is a substituted or non-substituted aromatic functional group, or Ar is nothing and the valence of the pyridine ring or fluorinated ring is completed with hydrogen; and
a donor of the structure:

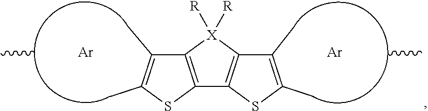

wherein each Ar is independently a substituted or non-substituted aromatic functional group, or each Ar is independently nothing and the valence of its respective thiophene ring is completed with hydrogen,
each R is independently hydrogen or a substituted or non-substituted alkyl, aryl or alkoxy chain;
or each R is a branched side chain having a branching point positioned more than one carbon atom from the backbone and along the side chain,
and

### X is C, C═C, Si, Ge, N or P.

15. The composition of matter of one or any combination of the previous examples, wherein the lyotropic semiconducting polymers each have the structure:

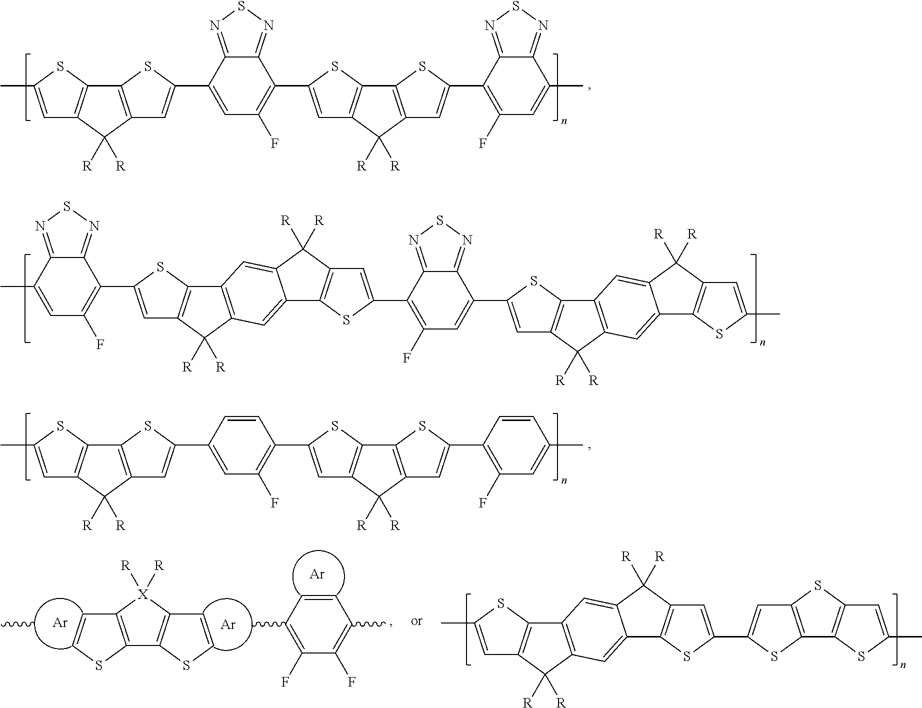

wherein R is a branched alkyl, aryl or alkoxy chain and n is an integer.

16. The composition of one or any combination of the previous examples, wherein the side chain is a branched C₅-C₅₀ alkyl chain.

17. The composition of one or any combination of the previous examples, wherein R is C1-BO, C3-BO, C4-BO, C5-BO, or C11-BO.

18. The composition of one or any combination of examples 14-17, wherein the branching point is at a position along the side chain between 2 and 20 atoms from the backbone.

19. An organic device comprising the composition of matter of one or any combination of the previous examples.

20. A transistor comprising a channel including the composition of matter of one or any combination of the previous examples.

21. The transistor of example 20, wherein the lyotropic semiconducting polymers are disposed on, and aligned with, grooves on a dielectric layer.

22. The transistor of example 21, wherein the dielectric layer comprises polyimide having a thickness between 25 nm and 200 nm.

23. The composition of matter of one or any combination of the previous examples, wherein the branching point is positioned so that a pi-pi stacking distance between the lyotropic semiconducting polymers is less than 3.7 Angstroms or in a range of 3.5-3.8 Angstroms.

24. A method of fabricating a composition of matter, comprising preparing lyotropic semiconducting polymers each having a backbone and a side chain attached to the backbone, wherein the side chain includes a branched chain having a branching point positioned further along the side chain so as to reduce the pi-pi stacking distance between the lyotropic semiconducting polymers.

25. A composition of matter, comprising lyotropic semiconducting polymers each having a donor-acceptor copolymer backbone and a side chain attached to the backbone, wherein the side chain includes a branched chain having a branching point positioned so that a pi-pi stacking distance between the lyotropic semiconducting polymers is less than 3.7 Angstroms or in a range of 3.5-3.8 Angstroms.

### BRIEF DESCRIPTION OF THE DRAWINGS

Referring now to the drawings in which like reference numbers represent corresponding parts throughout:

FIGS. 1A-1E. Structures of FBT copolymers with branched side chains illustrating the branched side chain for P2F-C1-BO (FIG. 1A), P2F-C3-BO (FIG. 1B), P2F-C4-BO (FIG. 1C), P2F-C5-BO (FIG. 1D), P2F-C11-BO (FIG. 1E), and associated stacking distance. The side chain branch point is moved back from the conjugated backbone with the goal of decreasing π-stacking distance and increasing intermolecular interactions. Intermolecular interactions have an impact on alignment and liquid crystalline thermodynamic interaction parameters.

FIG. 2A Optical absorbance of P2F-C1-BO as an isotropic solution in chlorobenzene (black trace) and as a liquid crystalline solution in hexanes (red trace). The low energy absorption indicates crystalline π-stacking in solution.

FIG. 2B Annealing solutions of P2F-C5-BO copolymers allows liquid crystalline mesophases to form, shown by UV-vis. Initially the UV spectrum indicates aggregation (black trace). Once heated the spectra blue-shifts, indicating aggregation is absent (red trace). Upon cooling an absorbance indicating crystalline π-stacking emerges (blue trace), evidence of self-assembly into a lyotropic liquid crystalline mesophase. These crystallites of P2F-C5-BO have a size of 2 microns as measured by DLS.

FIGS. 3A-3E. UV-vis on the liquid crystalline mesophases of all P2F copolymers P2F-C1-BO (FIG. 3A), P2F-C3-BO (FIG. 3B), P2F-C4-BO (FIG. 3C), P2F-C5-BO (FIG. 3D), and P2F-C11-BO (FIG. 3E). P2F-C1-BO has LC behavior showing crystalline π-stacking in selective solvents. All others display LC mesophases only upon solution annealing. This may be a result of the branch point moving further back and increasing intermolecular interactions, kinetically trapping disordered aggregates. The thermodynamically favorable crystalline structures can only be approached once given the activation energy to break up and reform. All solutions are 0.1 mg/mL.

FIGS. 4A-4J. Polarized optical microscopy of thin films and solutions of the indicated P2F copolymers and indicated solution. The films were drop cast from lyotropic solution (10 mg/mL) and solutions are observed at 150 mg/mL by dissolving 15 mg in 0.1 mL. In all cases the threaded texture of a nematic lyotropic liquid crystalline mesophases is observed, however the directional correlation of the threads seems to persist in one direction for a longer distance the further back the side chain branch point is moved. The paste was sandwiched between two glass slides. Lower concentrations can be used, even down to 10-20 mg/mL, but you need longer exposure on the microscope.

FIG. 5A-5E. GIWAXS line cuts for all P2F copolymers P2F-C1-BO (FIG. 5A), P2F-C3-BO (FIG. 5B), P2F-C4-BO (FIG. 5C), P2F-C5-BO (FIG. 5D), and P2F-C11-BO (FIG. 5E) spin cast from lyotropic solution (10 mg/mL) on Si wafers. The π-stacking reflection occurs between Q=1.5-1.8 Å⁻¹ and shows how the π-stacking distance becomes closer as the side chain branch point moves further from the conjugated backbone.

FIG. 5F plots stacking distance as a function of number of carbons between backbone and branch point.

FIGS. 6A-6E. Transistor data for all P2F copolymers P2F-C1-BO (FIG. 6A), P2F-C3-BO (FIG. 6B), P2F-C4-BO (FIG. 6C), P2F-C5-BO (FIG. 6D), and P2F-C11-BO (FIG. 6E), including representative transfer curves. Mobility is taken as an average of 4-6 measurements. Transistors are fabricated by drop coating solution (7 mg/mL) onto the Si substrate and thermally annealing at 200° C. for 8 minutes. Mobility values increase the further the branch point is from the conjugated backbone, as a result of closer π-stacking.

FIG. 7A. Illustration of shear alignment.

FIG. 7B-7D: POM (FIGS. 7B-7C) and UV-vis (FIG. 7D) of a thin film of P2F-C11-BO which has been shear aligned using shear coating on lyotropic liquid crystalline mesophases in chlorobenzene (7 mg/mL). POM shows that the LC mesophases are aligned in the direction of shearing, and polarized UV-vis shows that there is significant dichroism observed in shear coated films.

FIG. 8A. Schematic illustration of drop casting on an angle.

FIGS. 8B-8F: POM of P2F-C11-BO after drop casting on an angle. The thin film is shown under single polarizers to show the dichroism of thin film absorbance (FIGS. 8C-8F), and POM under dual crossed polarizers (FIG. 8B to show the alignment of LC mesophases during drying. A solvent chamber with chlorobenzene vapours was used to give more uniform films.

FIGS. 8G-8H: POM images of transistor devices fabricated using drop casing, for both bottom gate-bottom contact and bottom gate-top contact configuration.

FIG. 9A: Optical microscope image of the rubbed polyimide on glass.

FIGS. 9B-9D: Optical microscope images of P2F-C11-BO cast from chlorobenzene onto a rubbed polyimide layer imaged under a single polarizer (FIGS. 9B and 9C) and crossed polarizers (FIG. 9D).

FIG. 10A: Cross sectional schematic of drop cast transistor on 1.4 micron thick rubbed polyimide.

FIGS. 10B-10C: Transistor data for P2F-C11-BO on the rubbed polyimide layer, for the structure of FIG. 10A.

FIG. 11A: Cross sectional schematic of drop cast transistor on a 20 nanometer (nm) micron thick rubbed polyimide.

FIGS. 11B. Transistor data for P2F-C11-BO on rubbed polyimide (20 nm) layer before and after annealing.

FIG. 11C. π-stacking distance versus hole mobility as determined by OFET measurements of the devices on a silicon substrate. Closer π-stacking results in for efficient intermolecular charge transport and higher charge carrier mobilities.

FIG. 12: POM image of transistor fabricated using P2F-C11-BO on rubbed PVDF. P2F-C11-BO is the green material in the centre, while the gold contacts appear on the left and right.

FIG. 13. Transistor data for P2F-C11-BO on rubbed PVDF-HFP (20 nm) layer.

FIG. 14. Synthesis of indacenothiophene donor units and polymers

FIG. 15. Synthesis of P2F-IDT polymers with linear (n-C₁₆H₃₃) and branched (C11-BO) side chains.

FIGS. 16A-16B. Optical absorbance spectra of P2F-IDT copolymers in solution (chloroform, 0.05 mg/mL). The peak at 650 nm is attributed to π-stacking in solution. In the case of the P2F-IDT-branch, the π-stacking peak is more pronounced, which may indicate more crystalline π-stacking in solution.

FIG. 17A-17B. GIWAXS line cuts for P2F-IDT-branched and linear side chain polymers. In both polymers, reflections due to crystalline packing in the alkyl chain direction are observed (n00). In P2F-IDT-branched, there is a distinct reflection (0n0) that we attribute to π-stacking at 3.55 Å. Typically, IDT type copolymers either do not exhibit crystalline π-stacking, or show it at larger distances (˜4.1 Å). This reflection due to π-stacking is not observed in P2F-IDT-linear, supporting our assignment that the differences in optical absorbance are a result of closer and more crystalline π-stacking in P2F-IDT-branched. The improved π-stacking can be attributed to the side chain imparting ambiphilicity to the polymer, allowing for effective solution based assembly.

FIGS. 18A-18B. Transistor performance of P2F-IDT copolymers with C11-BO side chain. Transistors are measured as bottom gate-bottom contact devices with L=80 microns and W=1 mm. Transistors were spin coated onto the transistor substrate from solution (7 mg/mL in chloroform) and annealed at 200 C for 8 minutes. V_{SD}=−30V. Transistors are measured in duplicate and averaged. It can be seen that P2F-IDT-branch has a higher mobility. This can be attributed to the closer and more crystalline π-stacking, facilitating intermolecular charge transport. Additionally, the branched side chain improves solubility, allowing these polymers to be synthesized at higher molecular weights, further improving transistor performance.

FIG. 19. Design and structure of P2F-IDT polymers with linear and branched side chains.

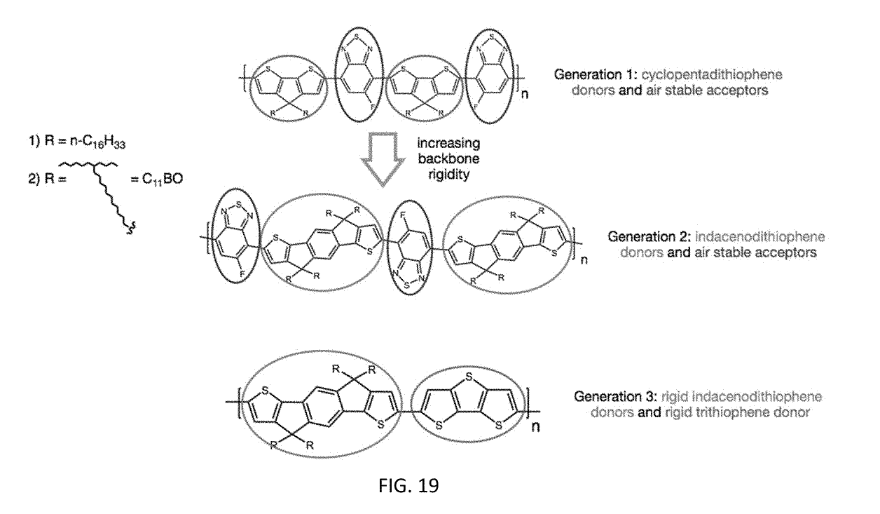

FIG. 20. Optical absorption spectra of IDT-TTT polymer.

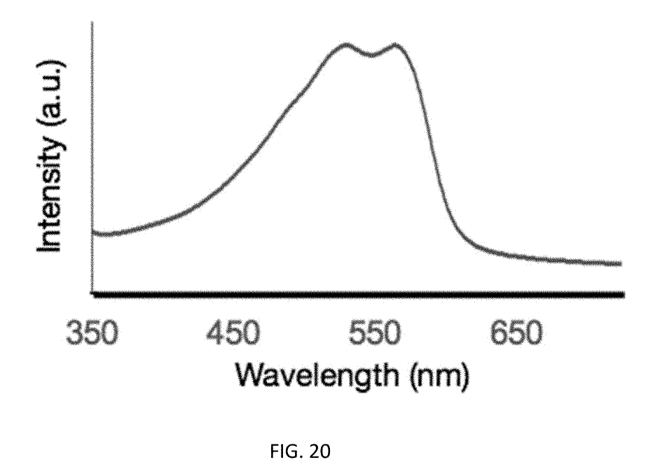

FIG. 21. Flowchart illustrating a method of fabricating a composition of matter according to one or more embodiments of the present invention.

FIG. 22A-22B. Transistor structures including the composition of matter according to one or more embodiments of the present invention.

FIG. 23 illustrates orientation of the branched side chains according to one or more embodiments.

### DETAILED DESCRIPTION OF THE INVENTION

In the following description of the preferred embodiment, reference is made to the accompanying drawings that form a part hereof, and in which is shown by way of illustration a specific embodiment in which the invention may be practiced. It is to be understood that other embodiments may be utilized and structural changes may be made without departing from the scope of the present invention.

### Technical Description

### 1. First Example: P2F

Conventional semiconducting polymers such as regioregular (4,4-dialkyl-4H-cyclopenta[1,2-b:5,4-b⁰]dithiophene and 5-fluorobenzo[2,1,3]thiadizaole donor and acceptor units (P2F) polymers have shown high mobility, but poor solubility and poor control over crystalline fraction, unit cell, and orientation. While liquid crystalline mesophases consisting of these polymers exhibit the favorable control over crystalline fraction and orientation, they possess a unit cell having a large π-stacking distance, ultimately resulting in materials with low charge carrier mobility.

The examples presented herein illustrate the effect of side chain branch point location on structure, formation, and electronic properties of semiconducting polymers comprising regioregular (4,4-dialkyl-4H-cyclopenta[1,2-b:5,4-b⁰]dithiophene and 5-fluorobenzo[2,1,3]thiadizaole donor and acceptor units (P2F) having the structure:

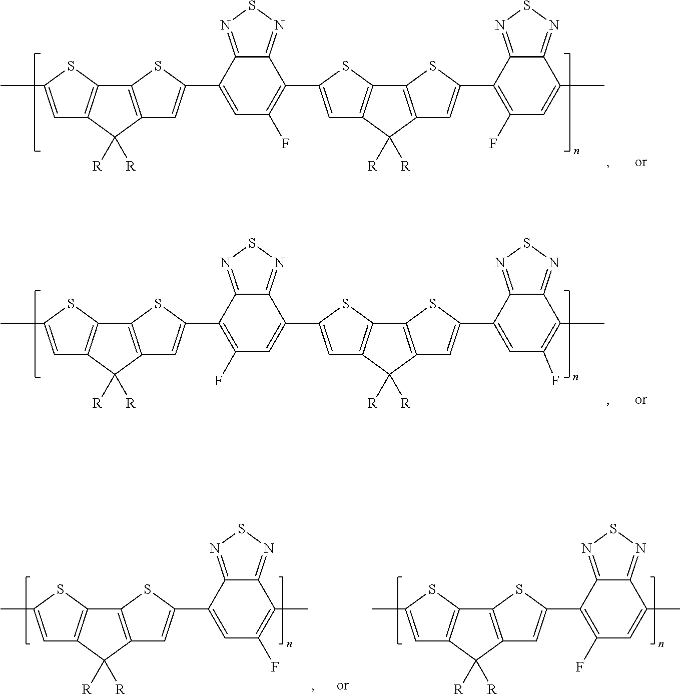

where R is a branched side chain.

### a. Structures

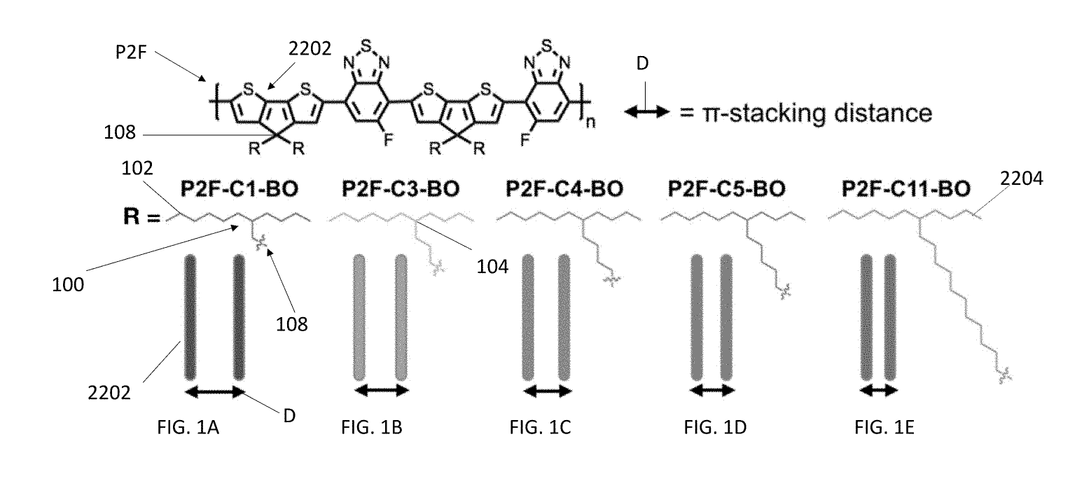

Using the methods described in the Experimental Section, a series of regioregular P2F copolymers with solubilizing alkyl side chains (e.g. 2-butyloctyl (BO) branched side chains) were synthesized with the branch points 100 at various distances from the conjugated backbone (1, 3, 4, 5 and 11 carbons away, named P2F-C1-BO, P2F-C3-BO, P2F-C4-BO, P2F-C5-BO, and P2F-C11-BO, respectively). The branched side chain increases solubility of the non-polar portion of the molecule, critical to providing the ambiphilicity necessary for forming lyotropic liquid crystalline mesophases. These polymers exhibit high solubility in many organic solvents (THF, hexanes, chloroform, chlorobenzene), as well as the distinct solvent and temperature dependent optical properties expected of self-assembled conjugated polymers. However, FIGS. 1A-1E illustrates that moving the branch point 100 further from the conjugated backbone decreases the π-stacking distance D (also referred to herein as pi-stacking distance, pi-pi stacking distance, or π-π stacking distance), allowing for stronger intermolecular electronic coupling, and improving the carrier transport.

Moreover, the studies presented herein establish how the structure, formation, and interactions of lyotropic mesophases can be tuned by side chain modification, and how side chain modification affects charge carrier mobility in thin film transistors.

### a. Characterization of the Example Structures

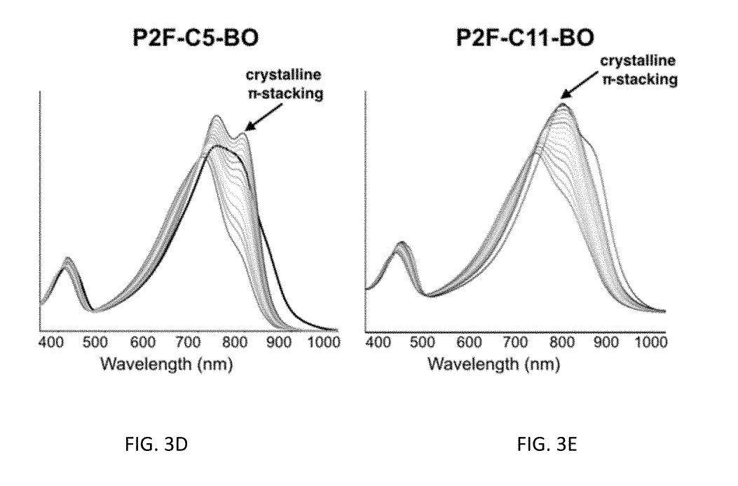

Lyotropic liquid crystalline mesophases in PCDTPT-type copolymers consist of extended polymer chains exhibiting close and ordered π-stacking perpendicular to the direction of chain extension in solution. ^{23, 24}This is apparent in the optical absorbance of lyotropic solutions, similar to that of highly crystalline thin films, in which planar and extended polymer chains and crystalline π-stacking are evidenced by a red-shifted absorbance spectrum with pronounced excitonic coupling. FIG. 3 illustrates these optical features are clearly present in P2F-C1-BO when comparing the spectrum dissolved in chlorobenzene (isotropic solution) and hexanes (lyotropic solution).

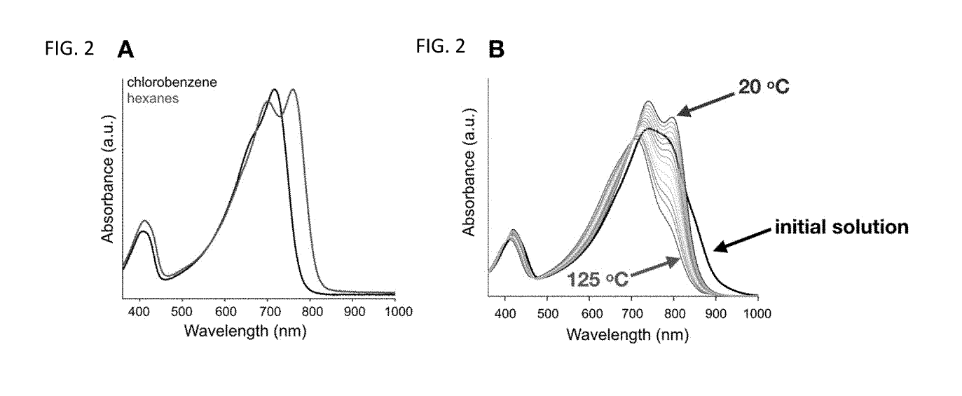

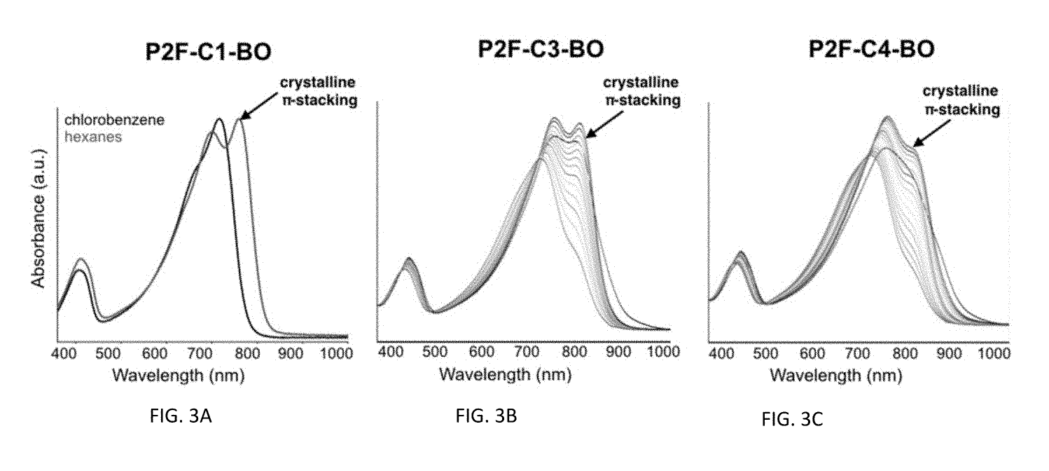

Polymers P2F-C3-BO, P2F-C4-BO, P2F-C5-BO and P2F-C11-BO exhibit markedly different behavior. When initially dissolved, they exhibit the broad featureless redshifted spectra associated with chain aggregation. ²⁸⁻³⁵This is confirmed using DLS, showing an aggregate size of around 2 microns (FIGS. 2A-2B). Upon heating to 125° C. in chlorobenzene, the absorbance spectra shows fully dissolved chains and the aggregates disappear as measured by DLS. When cooled at a rate of 1° C./minute, the aggregates return and a pronounced vibronic peak appears due to crystalline π-stacking. The feature persists at room temperature indefinitely, and indicates the self assembly process is vital for allowing the lyotropic liquid crystalline mesophase to form in these materials. This may be a result of the branch point moving further back and increasing intermolecular interactions, kinetically trapping disordered aggregates. The thermodynamically favorable crystalline structures can only be approached once given the activation energy to break up and reform. This self assembly of lyotropic liquid crystalline mesophases using solution annealing is observed for all P2F copolymers except for P2F-C1-BO, which forms lyotropic liquid crystalline mesophases without annealing (FIGS. 3A-3E).

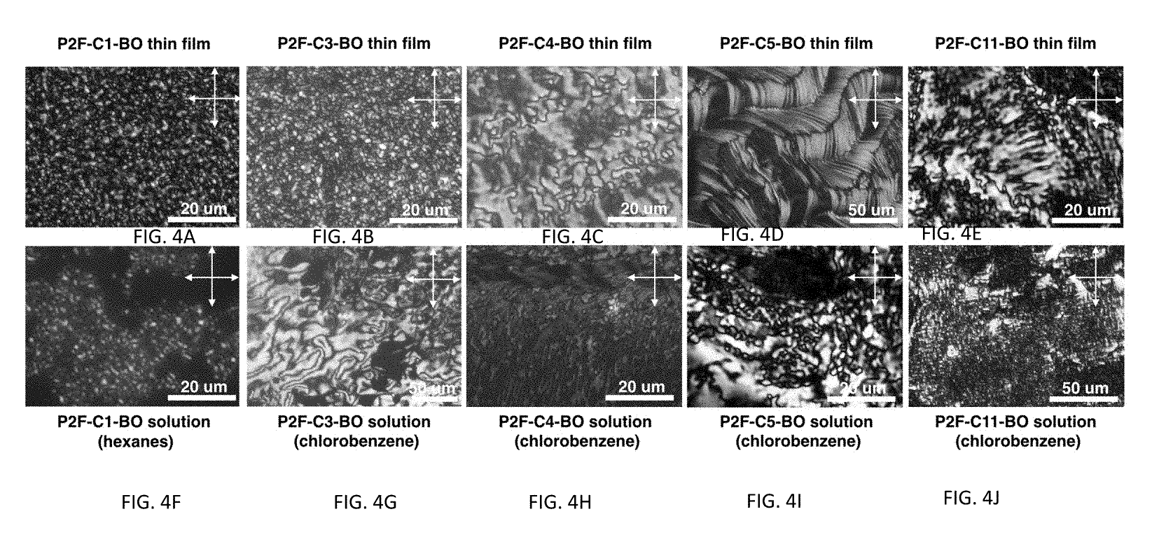

Birefringence is observed using polarized optical microscopy in both thin films and annealed solution for all P2F copolymers, showing that liquid crystalline mesophases with similar structure is present in solution, the nascent crystallinity can be readily transferred to thin films, and that the grain size in the LC texture tends to increase as the branch point moves further from the backbone. In all cases, the structure consists of extended polymer chains and ordered π-stacking. The threaded texture apparent in the birefringence indicates a nematic lyotropic liquid crystalline mesophase and is present in both lyotropic solutions and thin films cast from lyotropic solution (FIGS. 4A-4J).

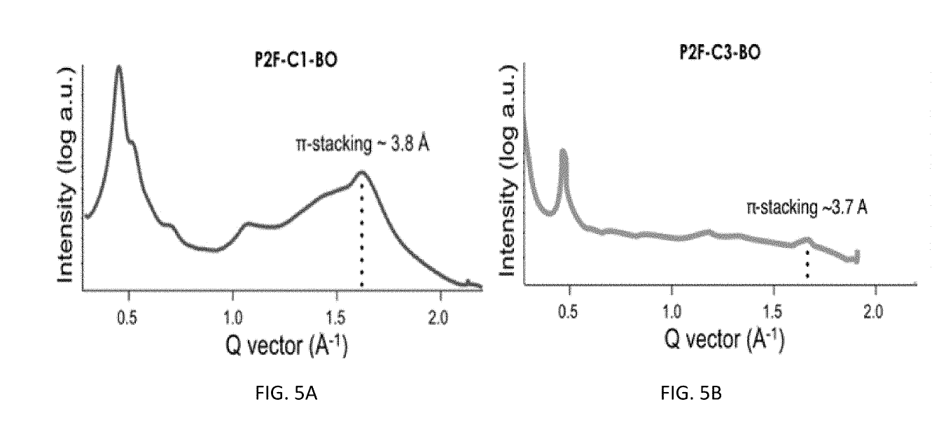

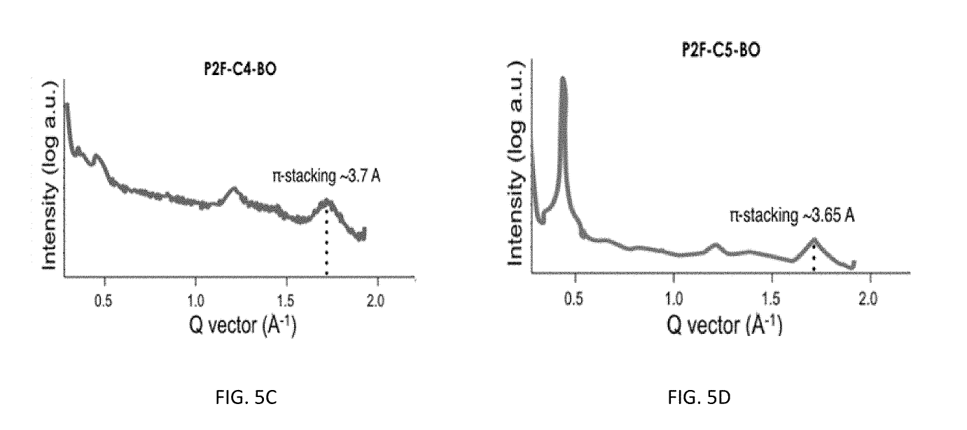

As the side chain branch point moves further from the conjugated backbone, the π-stacking distance within the lyotropic mesophase becomes closer, and intermolecular interactions increase. This is observed using grazing incidence wide angle X-ray scattering on spin coated films of P2F copolymers cast from lyotropic solution. As established for PCDTPT type copolymers, the P2F copolymers also show reflections at low q (0.2-0.6 Å⁻¹) corresponding to alkyl spacing (200) and at high q (1.2-1.8 Å⁻¹) corresponding to π-stacking (020). ^{9, 10, 27, 36, 37}However, FIGS. 5A-5F shows the π-stacking peak clearly moves to higher q values (closer distances) as the branch point moves from 1 to 11 carbons away from the backbone. This close and ordered pi stacking is vital for providing efficient intermolecular charge transport in transistors and these structural changes should manifest in distinct mobility improvements when used in thin film transistors. In fact, P2F-C11-BO exhibits π-stacking that is comparable to the P2F and PCDTPT copolymers that do not have branched side chains at all. Indeed, as illustrated herein, P2F-C11-BO material exhibits similar mobility to the high performance P2F and PCDTPT semiconductors without branched side chains, although with the added control over orientation and crystal structure provided by accessing liquid crystalline mesophases. It is important to note the distinctions between the present disclosure and that done on diketopyrrolopyrrole (DPP) polymers in reference⁴⁴. DPP polymers have side chains that are in the same plane as the polymer backbone, and thus the branch point does not significantly affect pi stacking. Reference⁴⁴ shows that pi stacking can only vary by 0.14 Å, and mobility changes by a factor of 8. The system of cyclopentadithiophene disclosed herein (having the side chains that are perpendicular from the backbone and thus the branch points significantly affecting pi stacking) shows a 0.25 A variation in pi stacking and a change in mobility by a factor of more than 100. In addition, the materials disclosed herein were designed with amphiphilicity in mind, which is critical to the formation of liquid crystalline mesophases. The authors of ⁴⁴ do not design, claim, or show liquid crystallinity in their materials. As such, the present disclosure was able to observe alignment during processing, a feature that is unique to liquid crystals.

### b. Transistor Fabrication Using the Examples and Characterization

The closer π-stacking allows for improved charge carrier mobility when these materials are evaluated in thin film field effect transistors. Given the similarity of electronic properties for these materials (identical semiconducting backbone), the improvement in mobility can be directly correlated to the improvement in molecular packing.

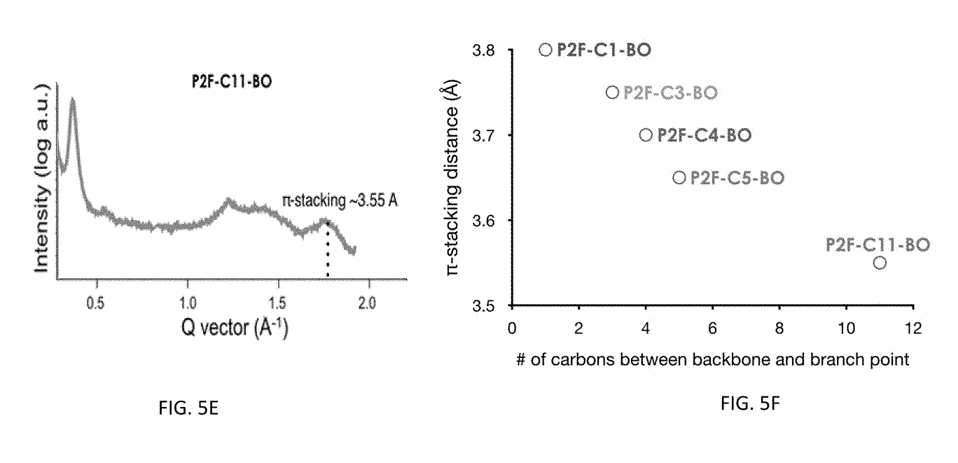

Transistors for P2F-C1-BO were fabricated from hexanes (lyotropic) solutions, and P2F-C3-BO, P2F-C4-BO, P2F-C5-BO and P2F-C11-BO were all fabricated from the self assembled lyotropic liquid crystalline mesophases produced from solution annealing at 7 mg/mL. Transistors were drop cast onto the substrates and the mobility was tested at a source drain voltage of −30V and −80V. Mobility values were determined as an average of at least 6 devices using the gradual channel approximation from the transfer curve between −30 and −50V and FIGS. 6A-6E shows there is a clear monotonic (steady) improvement in mobility as the branch point moves further away. Specifically, P2F-C1-BO has a mobility of 10⁻⁴cm²V⁻¹s⁻¹ (typical for a PCDTPT type donor-acceptor semiconducting polymer that has a branched side chains) and P2F-C11-BO has the highest mobility of 0.4 cm²V⁻¹s⁻¹, a value consistent with analogous polymers with linear side chains. Previously, many researchers have used PCDTPT polymers having side chains with branch points at C1, allowing for excellent control over crystalline morphology and solubility, but ultimately this has caused significant disruption to the electronic properties. ^{23, 24, 38, 39}The present disclosure, on the other hand, demonstrates that moving a branching point of the side chain further back from the backbone is a highly effective way of achieving the same control over solubility and crystalline structure during processing while maintaining the favorable electronic properties of PCDTPT-type copolymers. Moreover, the present disclosure expects the design rule (moving the branching point of side chain further from the backbone) to be generally applicable to all polymers consisting of indacenodithophene and cyclopentadithiophene donors or any polymer where branched side chains disrupt pi stacking (including polymers including thiophenes). In general, the present disclosure finds that the solution annealing process results in higher charge carrier mobilities.

### c. Experimental Section

### Materials

4H-cyclopenta[1,2-b:5,4-b′]dithiophene was synthesized from 4H-cyclopenta[1,2-b:5,4-b′]dithiophen-4-one (purchased from Ark Pharm Inc.) according to literature procedures. ⁴⁰2-butyoctylbromide was prepared from 2-butyloctanol according to literature procedures. ⁴¹n-Butyllithium was titrated with salicylaldehyde-phenylhydrazone immediately before use. ⁴²All other reagents were purchased from Sigma Aldrich and used as received. All solvents were purchased from Sigma Aldrich, dried, degassed, and stored over molecular sieves under nitrogen atmosphere prior to use. P2F-C1-BO, P2F-C3-BO, P2F-C4-BO, P2F-C5-BO, and P2F-C11-BO were synthesized using analogous adapted literature procedures, ²³⁻²⁶described in detail in the Supporting Information.

### Synthesis of C11-BO Side Chains

This same synthetic procedure is used for C3-BO, C4-BO, C5-BO, replacing the Grignard reagent with the analogous carbon chain. The synthetic procedure is adapted from (44).

### Synthesis of Grignard Reagent

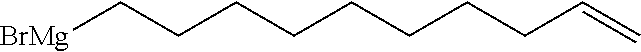

In a glove box, a 2-neck round bottom flask was outfitted with a condenser, stir bar, 0.83 g (34.2 mmol) of magnesium turnings, and 10 mg of Iodine, sealed and removed from the glove box and hooked up to flowing nitrogen. ˜45 mL of dry, degassed THF was added via syringe, followed by addition of 5.00 g (22.8 mmol) of 1-bromo-10-decene dropwise to maintain reflux. If reflux is not obtained after adding 1 mL of 1-bromo-10-decene, the flask is gently sonicated until it begins to self-heat. The reaction is refluxed overnight, cooled to room temperature, and titrated to determine the concentration prior to use (usually yielding a ˜0.4 M solution).

### Synthesis of C11-BO-Ene

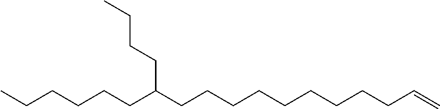 [SMILES: C=CCCCCCCCCCC(CCCC)CCCCCC]

5-(bromomethyl)undecane (4.23 g, 17 mmol), Lithium chloride (36 mg, 0.85 mmol), CuBr (122 mg, 0.85 mmol) were added to a schlenk flask in the glove box, which was sealed, removed, and hooked up to nitrogen. 10 mL of dry, degassed THF was added, and the flask was cooled to −5 C. The Grignard reagent was added dropwise and the reaction was stirred at −5 C->room temperature overnight. The reaction was quenched with aqueous ammonium chloride, diluted with hexanes, and the organic layer was washed with water twice and once with saturated NaCl. The organic layer was dried over magnesium sulphate, filtered and concentrated, and purified using 100% hexanes in column chromatography to yield a clear oil, 3.55 g (60% over 2 steps). The potential impurities of 1-bromo-10-decene, 1-decene, and 5-(bromomethyl)undecane may also be removed using a vacuum oven. ¹H-NMR (CDCl₃, 600 MHz): δ 5.81 (m, J=6 Hz, 1H), δ 5.01 (d, J=18 Hz, 1H), δ 4.93 (d, J=18 Hz, 1H) δ 2.04 (q, 2H), δ 1.38 (m, 2H) δ 1.4-1.1 (m, 31H), 667 0.89 (m, 6H) ¹³C-NMR (CDCl₃, 600 MHz) δ 139.21, 114.03, 37.38, 33.81, 33.72, 33.70, 33.39, 31.95, 30.13, 29.79, 29.67, 29.66, 29.62, 29.61, 29.51, 29.15, 28.95, 28.97, 26.68, 23.16, 22.70, 14.15, 14.10.

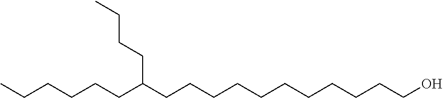 [SMILES: CCCCCCC(CCCC)CCCCCCCCCCCO]

### Synthesis of C11-BO—OH

An oven dried schlenk flask cooled under vacuum was hooked up to nitrogen and charged with a stir bar, C11-BO-ene (3.55 g, 11.5 mmol), dry, degassed THF, and cooled to 0 C. 1M Borane-THF solution (4.6 mmol, 4.6 mL) was added dropwise via syringe and the solution was stirred at 0 C for 2.5 hours. 8.4 mL of aqueous NaOH (3M) and 8.4 mL of aqueous Hydrogen peroxide (30%) solutions were added all at once, and the reaction was stirred at 0 C and warmed to room temperature over 2.5 hours. The reaction was quenched with saturated aqueous ammonium chloride and diluted with ethyl acetate. The organic layer was washed with water twice and once with saturated aqueous NaCl. The organic layer was dried over magnesium sulphate, concentrated and purified on a 100% hexanes column to yield a clear oil (1.47 g, 41%). ¹H-NMR (CDCl₃, 600 MHz): δ 3.63 (t, 2H), δ 1.56 (q, 2H), δ 1.38 (m, 1 H) δ 1.4-1.1 (m, 34H), δ 0.89 (m, 6H) ¹³C-NMR (CDCl₃, 600 MHz) δ 63.04, 37.37, 33.70, 33.37, 32.80, 31.94, 30.14, 29.81, 29.69, 29.66, 29.60, 29.59, 29.43, 28.95, 26.69, 25.73, 23.15, 22.69, 14.14, 14.09.

### Synthesis of C11-BO—Br

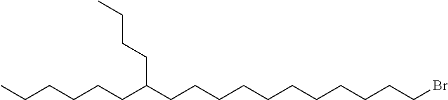 [SMILES: CCCCCCC(CCCC)CCCCCCCCCCCBr]

A round bottom flask is charged with a stir bar, C11-BO—OH (1.47 g, 4.5 mmol), triphenylphosphine (1.32 g, 5.0 mmol), and 40 mL dichloromethane. The reaction is cooled to 0 C, and N-bromosuccinimide is added portion wise (0.962 g, 5.4 mmol) over 15 minutes. The reaction is stirred at 0 C->room temperature overnight, concentrated on a rotovap, filtered through a silica gel plug with hexanes to recover the product as a clear oil (1.63 g, 92%). ¹H-NMR (CDCl₃, 600 MHz): δ 3.40 (t, 2H), δ 1.85 (q, 2H), δ 1.42 (m, 1H) δ 1.4-1.1 (m, 34H), δ 0.89 (m, 6H) ¹³C-NMR (CDCl₃, 600 MHz) δ, 37.38, 33.97 33.70, 33.38, 32.84, 31.95, 30.13, 29.82, 29.67, 29.62, 29.54, 29.43, 28.96, 28.76, 28.18, 26.67, 23.16, 22.70, 14.15, 14.09.

### Instrumentation and Methods

Microwave reactions were performed using a Biotage microwave reactor in a mixture of dry, degassed xylenes and dimethylformamide using procedures outlined in the Supporting Information. Nuclear magnetic resonance (NMR) spectra were obtained on Varian 600 MHz spectrometer. Gel permeation chromatography (GPC) was performed in chloroform (CHCl₃) on a Waters 2690 Separation Module equipped with a Waters 2414 Refractive Index Detector. Molecular weights were calculated relative to narrow PS standards. DSC was conducted on a Perkin Elmer DSC 8000 outfitted with a liquid nitrogen cooling module. Polarized optical microscopy was conducted with an Olympus BX51 microscope outfitted with a Linkam THMS600 temperature controlled stage. All polymer films and solutions were imaged while sandwiched between glass microscope slides. UV-vis spectra were collected at a concentration of 0.2 mg/mL using a Shimadzu 3600 UV-vis-NIR s24pectrometer outfitted with a heated sample stage. Dynamic Light Scattering was performed using a Viscotek 802 DLS with a 60 mW, 825 nm laser light source at a concentration of 0.5 mg/mL. Grazing Incidence Wide Angle X-ray Scattering and Wide Angle X-ray Scattering measurements were performed at beamline 11-3 at the Stanford Synchrotron Radiation Lightsource (SSRL) with an X-ray wavelength of 0.9752 Å. Thin films for GIWAXS were spin coated onto silicon wafers from a 10 mg/mL solution of the indicated solvent for 60 seconds at 1500 RPM.

### Transistor Fabrication and Testing

Highly-doped silicon was used as the gate contact with a 300 nm silicon dioxide layer as the dielectric. Source and drain contacts (5 nm Ni/50 nm Au) were deposited using standard two-step photolithography. Before polymer deposition, the substrates were cleaned by sonication in acetone and isopropanol for 3 minutes each, and were then dried in an oven under ambient atmosphere at 120° C. for 20 minutes. The substrates were treated with UV-O₃ for 20 minutes. Subsequently, the substrates were then passivated using decyltrichlorosilane (from Gelest Chemicals) from a 0.2 vol % solution in toluene at 80° C. for 25 minutes. P2F polymer solutions were drop cast onto the substrates at 7 mg/mL. The final device architecture (from bottom to top) for these bottom gate, bottom contact field-effect transistors was Si (500 μm)/DTS-treated SiO2 (300 nm)/Ni (5 nm)/Au (50 nm)/blend layer.

The mobility of blend devices were obtained by fitting the following equation to the saturation regime transfer characteristics: IDS=(W/2L) Ci μ (V_{GS}-Vₜₕ)², where W is the channel width (1 or 2 mm), L is the channel length (80 or 160 μm), Ci is the gate dielectric layer capacitance per unit area (10 and 11.5 nF/cm²), V_{GS} is the gate voltage, Vₜₕ is the threshold voltage, and I_{DS} is the source-drain voltage. Devices were measured under nitrogen in a glovebox using a Signatone 1160 probe station and Keithley 4200 semiconductor parametric analyzer. Mobility values were calculated from a gate voltage range of −30V to −50 V at a source-drain voltage of −80 V.

### 2. Second Example: Alignment Techniques

### a. Shear Coating

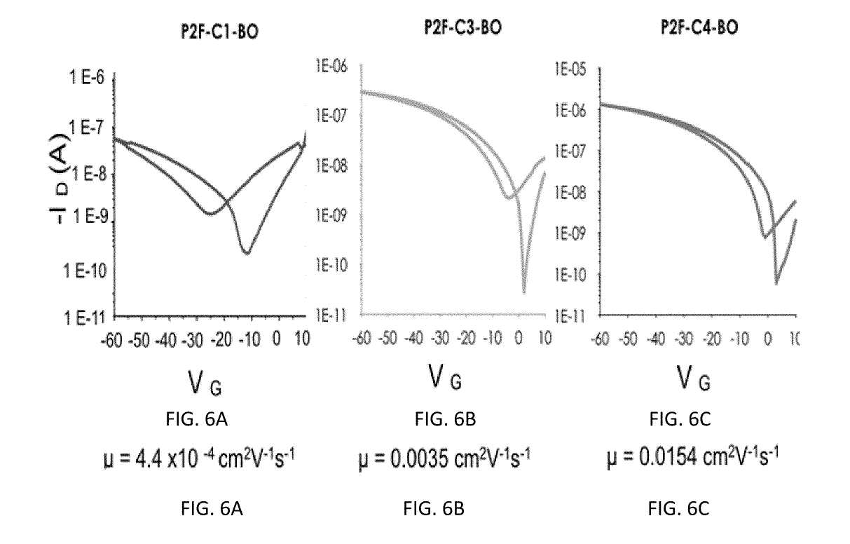

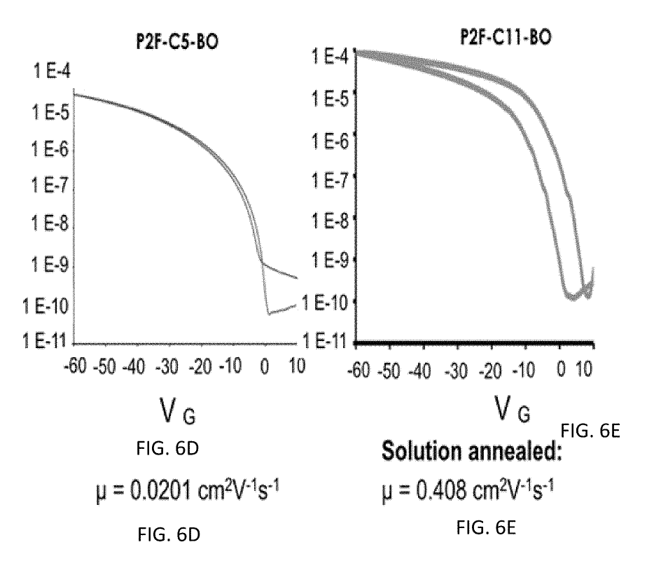

FIGS. 7A-7C show that the liquid crystalline materials can be aligned using shear coating (an equilibrium coating process). Shear coating allows for further increases in carrier mobility.

### b. Drop Casting

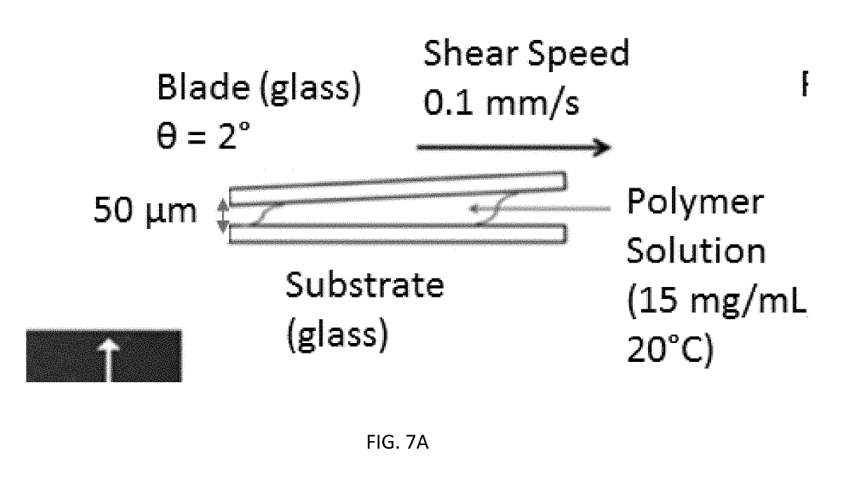

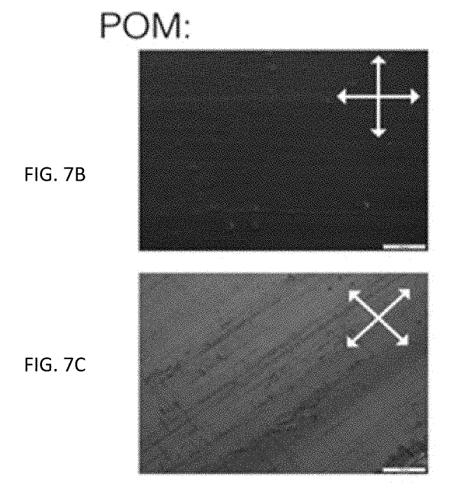

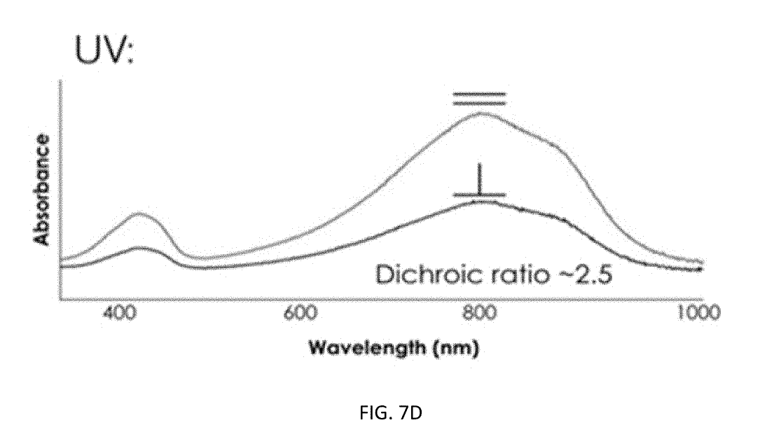

FIGS. 8A-8E illustrate that drop casting P2F-C11-BO from chlorobenzene onto a substrate angled at ˜15 degrees, including drying on the angle, resulted in significant alignment of liquid crystalline texture (as illustrated by the dichroism of absorbance under singly polarized filters and also by the aligned texture of the liquid crystalline mesophase).

Transistor devices were fabricated to test the effect the drop casting method had on the measured hole mobility. P2F-C11-BO used in all drop casting experiments in this section was synthesized having an Mn=100 kDa.

In the bottom gate bottom contact device, the alignment can clearly be seen on the electrodes but not in the channel (as illustrated in FIG. 8F). This drying effect is likely due to capillary action in between the electrodes preventing any improvement in mobility.

For the bottom gate top contact devices, 35 nm thick gold electrodes were evaporated after the drop casting. Although good alignment of the liquid crystalline texture was observed after drop casting, overall there was no mobility improvement for the parallel oriented devices (alignment parallel to the channel length) as compared to the perpendicular oriented devices (alignment perpendicular to the channel length). The lack of mobility improvement results from non-uniform directional drying preventing alignment from being parallel or perpendicular to the channel length across the entire substrate.

### c. Polymer Alignment on Polyimide Substrate

In this example, rubbed polyimide was deposited as a dielectric layer on top of the SiO₂ dielectric layer in a bottom-gate top contact transistor architecture.

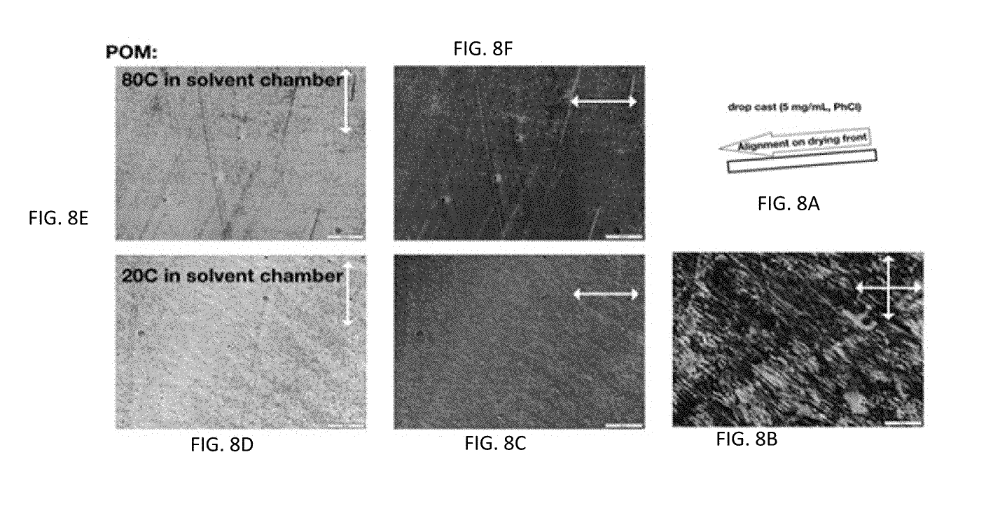

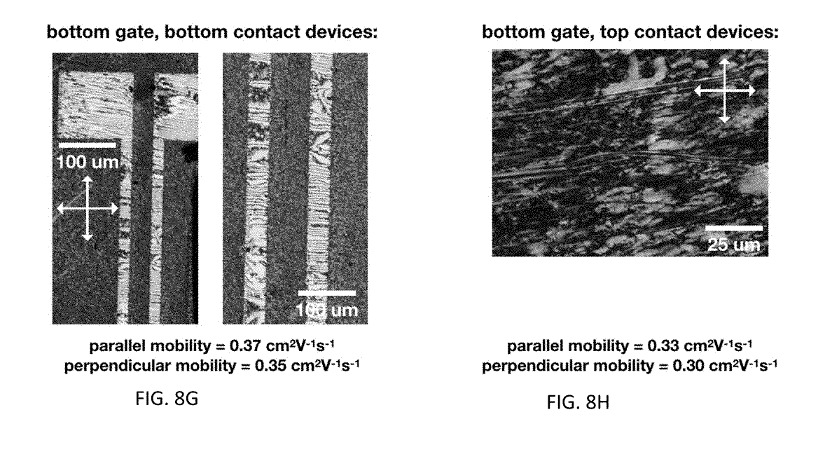

In a first experiment, the polyimide alignment layer was deposited as the precursor solution (CAS #31942-21-9, catalogue number 431206 from Sigma Aldrich); spin coated at 9999 RPM for 60 seconds; and then annealed at 200° C. in air for 3 hours, resulting in a thin yellow film coating the Si/SiO₂ substrate. The rubbing treatment was achieved by applying velvet to the polyimide substrate, applying 1 g per square centimeter of force onto the polyimide substrate using a weight, and moving the weight across the fabric for a distance of 150 cm. Using the spin coating for 60 seconds and applying 1 g/cm² of force resulted in the uniform, featureless, smooth polyimide film shown in FIG. 9A.

Drop casting P2F-C11-BO on the substrate with the rubbed polyimide alignment layer, and then allowing the P2F-C11-BO to dry, results in excellent alignment of the P2F polymer (FIGS. 9B-9D). P2F-C11-BO is drop cast on a flat substrate from 1 mg/mL chlorobenzene solution. As can be seen with the top left and top right images under a single polarizer, the film exhibits significant dichroism. When the single polarizer is aligned perpendicular to the direction of rubbing (FIG. 9B), the film cannot be seen, whereas when the polarizer is aligned with the direction of rubbing, the film significantly absorbs light. This optical dichroism indicates significant molecular anisotropy achieved from drop casting.

When the film is observed under crossed polarizers, the liquid crystalline texture of P2F-C11-BO is clearly aligned with the direction of rubbing the polyimide. Previously simply having aligned materials by POM or UV absorbance didn't necessarily indicate improvement in mobility, so we tested these materials in a bottom-gate bottom contact transistor architecture to confirm the effects of using an aligned polyimide dielectric.

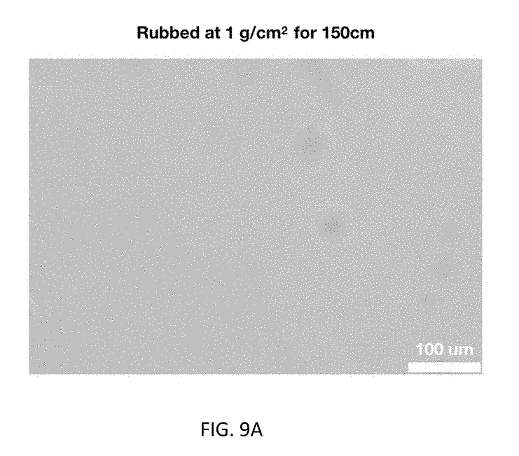

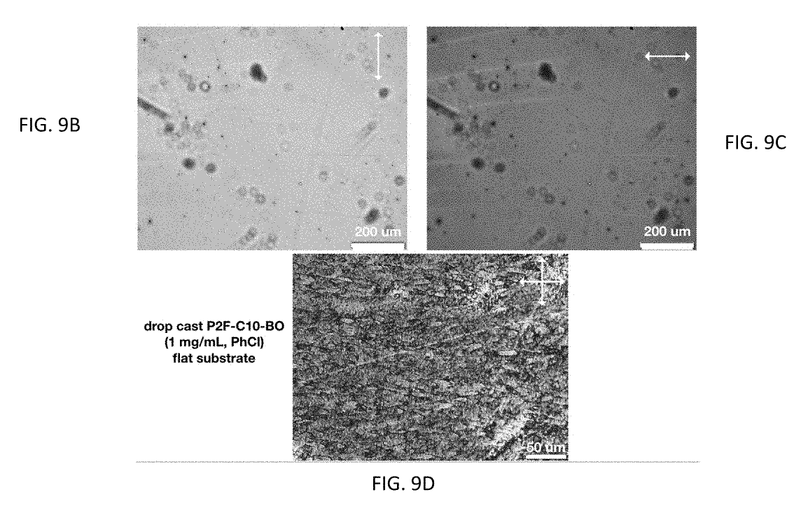

In a second experiment, transistors were fabricated using the same technique highlighted above except the spin coating was for 5 minutes and the rubbing was performed using 5 g/cm² of force (achieving a 1.4 micron thick layer of polyimide) and the P2F-C11-BO was drop cast from chlorobenzene at 2 mg/mL before being allowed to dry. The resulting device architecture illustrated in FIG. 10A is as follows (from bottom to top): Si (500 μm)/DTS-treated SiO2 (300 nm)/Polyimide (1.2 microns)/P2F-C11-BO (100 nm)/Gold Contacts (35 nm).

In this example, the polyimide layer is very thick, limited by the viscosity of our current polyimide solution. Using electronics grade NMP to dilute this solution can achieve lower viscosities.

The transistor performance shown in FIGS. 10B-10C was examined at a channel length of 80 microns and a gate voltage of −30 V. There is a significant anisotropy to the mobility when channels are parallel and perpendicular to the direction of substrate rubbing. Before annealing, the ratio of parallel mobility to perpendicular mobility is around 10-25 (mobility of ˜0.01 cm²V⁻¹s⁻¹ parallel, 0.001 cm²V⁻¹s⁻¹ perpendicular), however this increases to around 40 after annealing at 200° C. for 8 minutes. However, no further mobility increase was observed after annealing for 30 minutes.

The inventors hypothesized that a thinner polyimide dielectric later on top of the SiO₂ would yield higher currents and higher mobilities. Specifically, the inventors hypothesized that the field experienced by the semiconducting polymer is much weaker than reported when the semiconducting polymer is too far away from the gate, thereby lowering mobility.

To investigate the effect of polyimide layer thickness, a third experiment was performed wherein the polyimide solution was diluted to 1% in NMP, and the polyimide solution was spin coated at 1000 RPM for 15 minutes, followed by baking at 200° C. for 3 hours to achieve a 20-25 nm thick layer of polyimide as measured by ellipsometry. The polyimide layer was rubbed, the P2F-C11-BO was drop cast on the substrate, and transistors were prepared in the same manner as described for the second experiment. Further annealing does not increase the anisotropy and lowers the current.

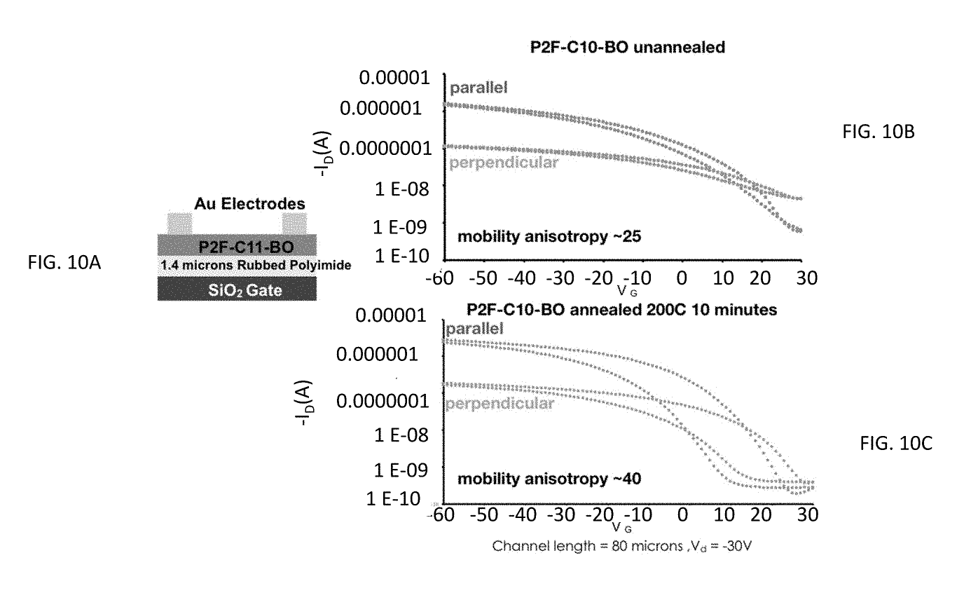

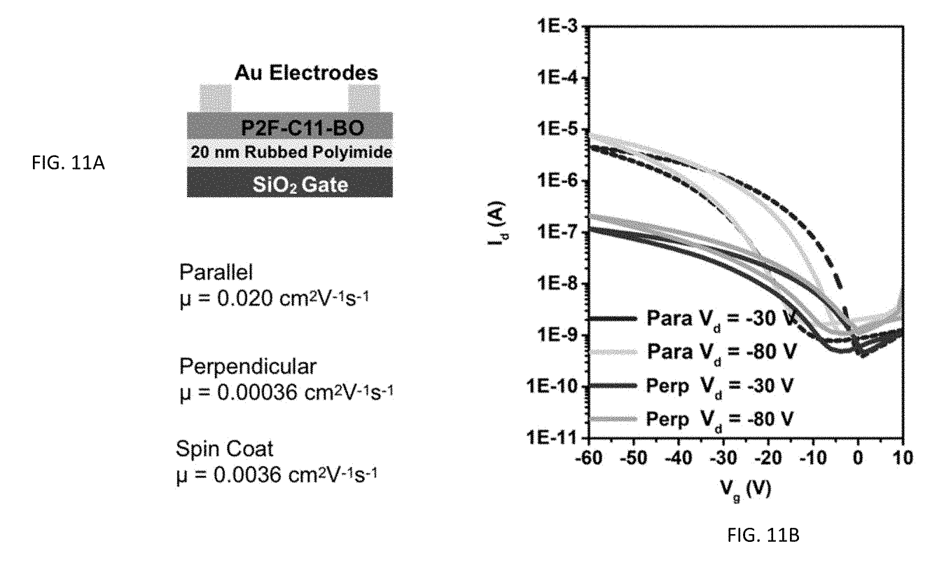

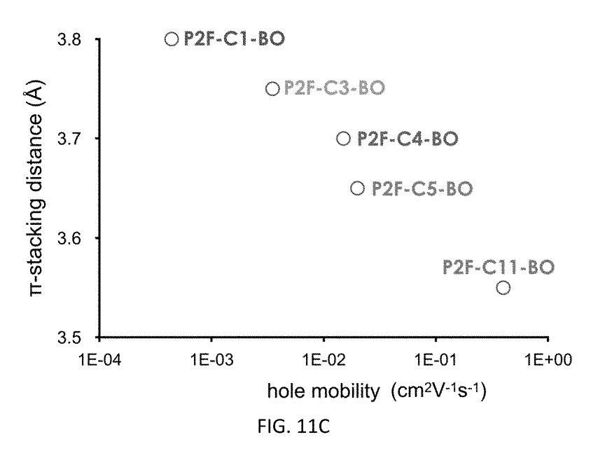

FIG. 11 shows improved current and improved mobility was achieved for transistors prepared using the thinner polyimide layer of the third experiment, as compared to the thicker polyimide of the second experiment. The maximum ratio of parallel and perpendicular mobility was 44, after annealing at 200° C. for 8 minutes (mobility μ=0.020 cm²V⁻¹s⁻¹ parallel, 0.00036 cm²V⁻¹s⁻perpendicular). The mobility numbers are lower, possibly due to impurities in the dielectric layer from rubbing, the polyimide precursor solution, or the baking step which occurs under ambient conditions. Microscope images show that there are clearly dust specks on the dielectric layer. While good alignment was observed on the thinner layer of polyimide, layers of polyimide thinner than 20 nm could not be observed due to incomplete polyimide coverage after baking.

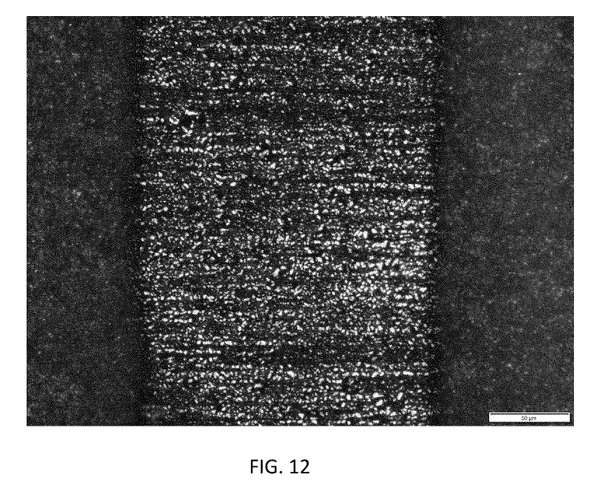

FIG. 12 shows a POM image of a transistor fabricated using P2F-C11-BO on rubbed PVDF. P2F-C11-BO is the green material in the centre, while the gold contacts appear on the left and right.

### d. Alternative Dielectrics

Transistors in a bottom gate device could not be fabricated using common polymer dielectrics such as polystyrene and PMMA. Specifically, polystyrene has similar solubility to the P2F based polymer and therefore deposition of the P2F based polymer would dissolve the dielectric. Moreover, PMMA exhibited wetting issues with the semiconducting polymer solution.

On the other hand, transistors could be fabricated using a PVDF-HFP dielectric. The transistors were fabricated by casting the PVDF-HFP solution from methyl-ethyl ketone (5 mg/ml) and spin coating the PVDF-HFP solution onto silicon at 1500 RPM for 3 minutes to achieve a 20 nm thick layer, as measured by ellipsometry. These substrates were rubbed with a velvet cloth and used to fabricate bottom gate top contact transistors exactly as was done before in Example c.

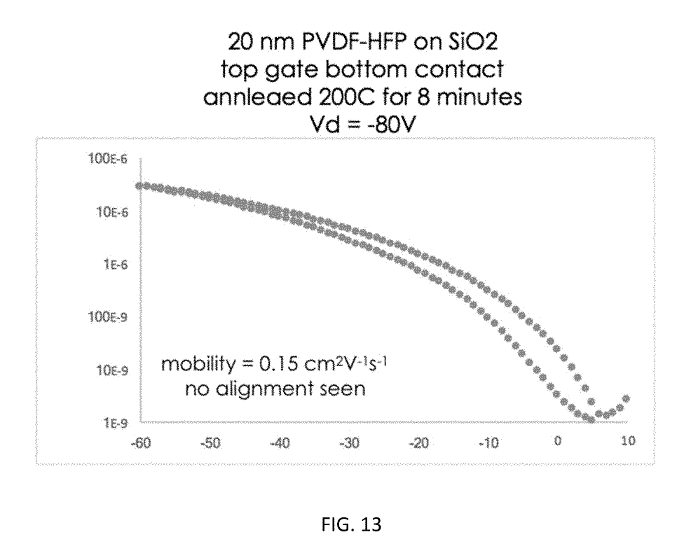

While PVDF-HFP works better as a dielectric and yields transistors with higher current and higher mobility, mobility anisotropy was not observed (see FIG. 13). Even though there appeared to be some alignment in the channel using POM, this may be due to high barrier to wetting between the two polymers.

### 3. Third Example: Indacenodithiophene P2F (P2F-IDT) Copolymers with Extended and Rigid Donor Units

### a. Synthesis

P2F-IDT copolymers have more rigid donor units that reduce torsional disorder along the backbone which may increase mobility. However, the synthesis of indacenodithiophene units (or analogous units of higher rigidity) is challenging. In two examples, commercially available indacenothiophene units were used. In other examples, the indacenothiophene units were synthesized according to procedures described herein.

Initial synthesis difficulties arose from poor solubility of the indacenothiophenes, rendering the P2F-IDT difficult to purify. The first attempt to purify by attaching side chains failed, possibly due to low purity of the starting material. The second attempt purified the compound's starting materials by recrystallization or sublimation prior to the attachment of the side chains.

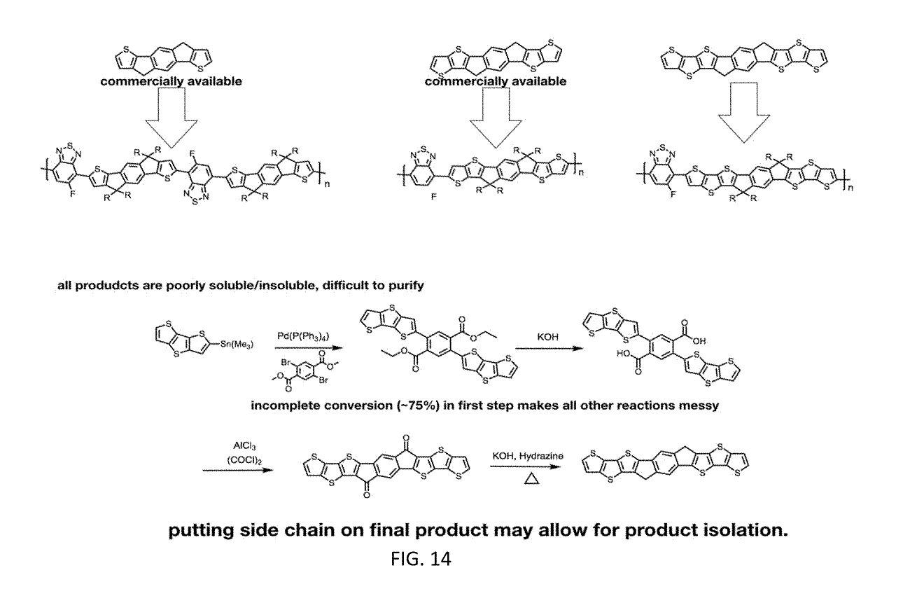

FIG. 14 illustrates a scheme for synthesis of a rigid indacenodithophene based donor for the P2F style copolymer.

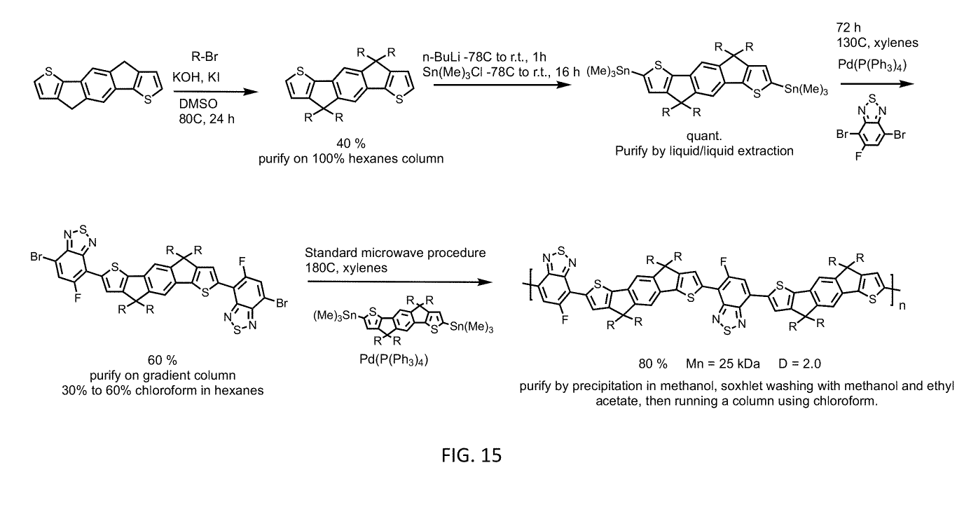

FIG. 15 illustrates a synthesis scheme for P2F-IDT polymers with linear (n-C₁₆H₃₃) and branched (C11-BO) side chains. P2F-IDT-C11-BO (branched C11-BO side chain) was synthesized from commercially available indacenodithophene and with comparable yields and purification procedures as can be achieved for P2F. Moreover, P2F-IDT-C11-BO exhibits good solubility in hexanes, chloroform, THF, and a variety of other organic solvents.

### b. Characterization

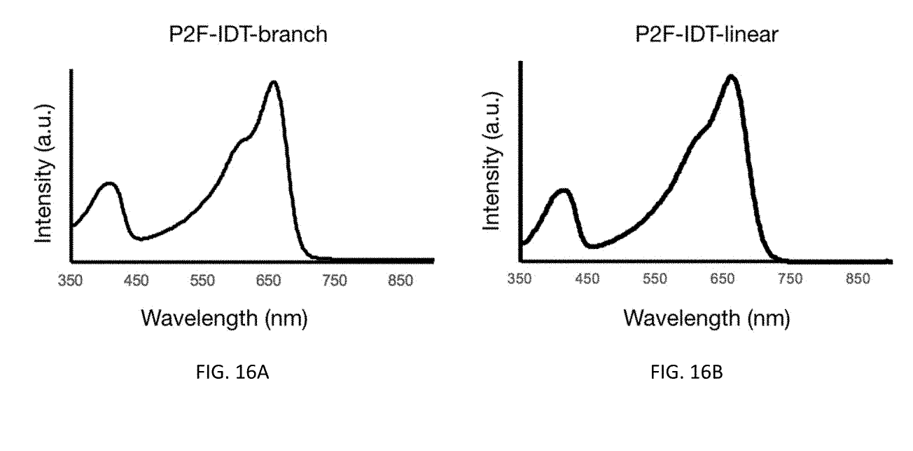

The optical absorption characteristics of rigid donor acceptor P2F-IDT polymers were explored as a function of the side chain. A significant difference between the polymers is the solubility. P2F-IDT-branch polymers have much improved solubility in a wider variety of solvents, including non-polar solvents which have been shown to improve crystalline π-stacking in solution. Evidence is seen by examining their optical absorption profiles—the branched side chain polymer exhibits a slightly sharper, low energy peak at 650 nm when compared to the polymer with linear side chains, which may indicate some π-stacking in solution (FIGS. 16A-16B).

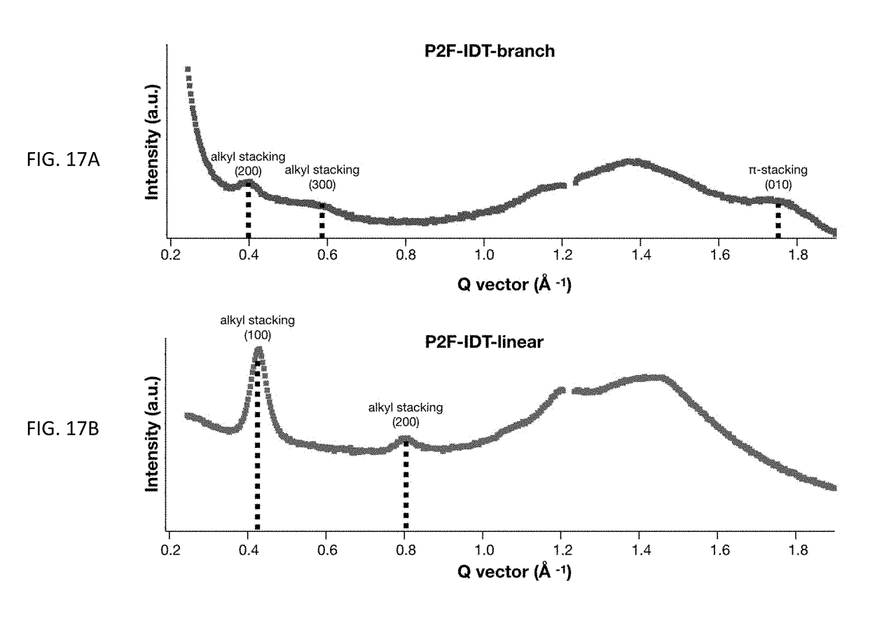

The effect of having a branched side chain on π-stacking is directly examined using GIWAXS (FIGS. 17A-17B). FIGS. 17A-17B illustrate distinct π-stacking in P2F-IDT-branched polymer, but not in P2F-IDT-linear polymer. Typically, polymers based off indacenodithiophene are made using linear side chains and do not exhibit ordered π-stacking. We observe highly crystalline alkyl spacing for the P2F-IDT-linear polymer, but no crystalline π-stacking. The pronounced π-stacking in the P2F-IDT-branched polymer occurs at a spacing of 3.55 Å, and is attributed to the improved solubility and intermolecular interactions (as evidenced by the UV-vis measurements). Closer π-stacking is desired for intermolecular charge transfer and should lead to improved mobility in transistors.

### c. Transistor Performance

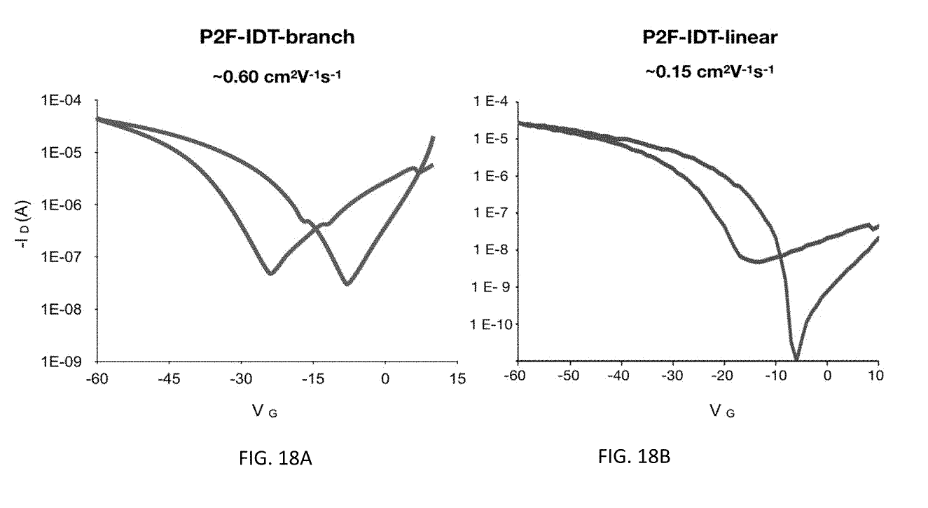

P2F-IDT-C11-BO was tested in a bottom gate bottom contact transistor configuration spin coated from chloroform (FIGS. 18A-18B). The transistor exhibits good mobility which the inventors believe can be improved by fractionating to isolate higher molecular weight of this polymer.

P2F-IDT polymers with branched side chains (C11-BO) exhibit higher mobility than their linear side chain (n-C₁₆H₃₃) analogues. P2F-IDT-linear has a measured hole mobility of 0.15 cm²/(Vs), similar to literature reports of analogous polymers. The P2F-IDT-branch has a significantly improved hole mobility of 0.60 cm²/(Vs), which we attribute to the closer and more crystalline π-stacking, as well as the improved solubility allowing for synthesis to higher molecular weight. These features are allowed by the unique chemical structure of our branched side chain. It is also important to note that the analogous polymer with a less rigid cyclopentadithiophene donor in the backbone has a lower measured mobility of 0.40 cm²/(Vs), showing the advantageous effect of increasing the rigidity of the backbone, along with the advantageous effect of including the branched side chain.

### 4. Fourth Example: IDT-TTT

A polymer with a rigid donor (indacenodithiophene) is paired with another rigid donor (dithieno[3,2-b:2′,3′-d]thiophene, TTT) in place of benzothizdiazole to make a more rigid polymer.

In the fourth example, a rigid donor-rigid donor polymer comprising IDT-TTT was tested in a bottom gate bottom contact device. Highly-doped silicon was used as the gate contact with a 300 nm thick silicon dioxide layer as the dielectric. Source and drain contacts (5 nm Ni/50 nm Au) were deposited using standard two-step photolithography. Before polymer deposition, the substrates were cleaned by sonication in acetone and isopropanol for 3 minutes each, and were then dried in an oven under ambient atmosphere at 120° C. for 10 minutes. The substrates were treated with UV-O₃ for 15 minutes and submerged in dilute Ni etchant to etch the Ni adhesion layer. Subsequently, the substrates were dried in an oven under ambient atmosphere at 120° C. for 10 minutes, treated again with UV-O₃ for 15 minutes, and then passivated using decyltrichlorosilane (from Gelest Chemicals) from a 1 vol % solution in toluene at 80° C. for 25 minutes. The substrates were then rinsed and sonicated in toluene and dried under nitrogen flow. Polymer was coated using spin coating from a 5 mg/mL solution at 2000 RPM for 60 seconds. The final device architecture (from bottom to top) for these bottom gate, bottom contact field-effect transistors was Si (500 μm)/DTS-treated SiO2 (300 nm)/Ni (5 nm)/Au (50 nm)/blend layer.

The mobilities of blend devices were obtained by fitting the following equation to the saturation regime transfer characteristics: I_{DS}=(W/2L) Ci μ (V_{GS}-Vₜₕ)², where W is the channel width (1 or 2 mm), L is the channel length (80 or 160 μm), Ci is the gate dielectric layer capacitance per unit area (10 and 11.5 nF/cm²), V_{GS} is the gate voltage, Vₜₕ is the threshold voltage, and IDS is the source-drain voltage. Devices were measured under nitrogen in a glovebox using a Signatone 1160 probe station and Keithley 4200 semiconductor parametric analyzer. Mobility values were calculated from a gate voltage range of −30V to −50 V at a source-drain voltage of −30 or −80 V.

Mobility values for this polymer were evaluated to be about 0.001 cm²V⁻¹S⁻¹ from preliminary device test.

### 5. Experimental Methods for Examples 3 and 4

Monomers and polymers were synthesized according to the following procedures.

### Synthesis of C11-BO Side Chains

This same synthetic procedure is used for C3-BO, C4-BO, C5-BO, replacing the grignard reagent with the analogous carbon chain. The synthetic procedure is adapted from Fu, B.; Baltazar, J.; Sankar, A. R.; Chu, P.-H.; Zhang, S.; Collard, D. M.; Reichmanis, E. Enhancing Field-Effect Mobility of Conjugated Polymers Through Rational Design of Branched Side Chains. Adv. Funct. Mater. 2014, 24 (24), 3734-3744.

### Synthesis of Alkylated IDT

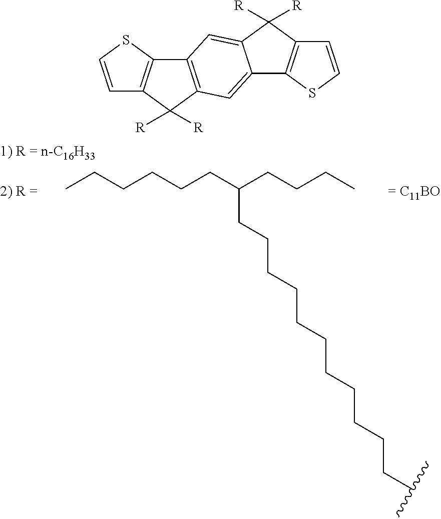

### General Procedure

A 50 mL roundbottom flask is loaded with a stir bar, 4,9-dihydro-s-indaceno[1,2-b:5,6-b′]dithiophene (0.290 g, 1.09 mmol) and potassium t-butoxide (1.41 g, 12.5 mmol), then purged with nitrogen. 10 mL dry, degassed DMF was added, and the mixture was heated to 90 C for 30 minutes under nitrogen. The corresponding alkyl bromide (5.45 mmol) was added dropwise via syringe, and the reaction mixture was stirred for 72 hours at 90 C under nitrogen. The reaction mixture was poured into water, and the aqueous layer was extracted with hexanes (100 mL) three times. The organic layer was dried over magnesium sulfate, filtered, concentrated on the rotovap and purified using flash chromatography (100% hexanes) to yield a pale yellow oil. (570 mg, 0.414 mmol, 38%).

1) n-C₁₆H₃₃ chain: ¹H NMR (600 MHz, CDCl₃) δ 7.23-7.26 (m, 4H), 6.9 (s, 2H), 1.93 (m, 4H), 1.72 (m, 4H), 0.96-1.36 (m, 112H), 0.69-0.83 (m, 12H);

2) C11-BO chain: ¹H NMR (600 MHz, CDCl₃) δ 7.23-7.26 (m, 4H), 6.9 (s, 2H), 1.93 (m, 4H), 1.72 (m, 4H), 0.96-1.36 (m, 160H), 0.69-0.83 (m, 12H); ¹³C NMR (100 MHz, CDCl₃): δ 155.08, 153.20, 135.63, 128.26, 126.08, 121.73, 110.91, 53.68, 39.13 37.48, 33.74, 33.48, 31.97, 30.19, 30.00, 29.88, 29.64, 29.40, 28.96, 26.67, 24.22, 23.17, 22.78, 14.15.

HRMS (MALDI) m/z: calcd for C₁₀₄H₁₈₆S₂, 1499.3996; found, 1499.3989.

### Synthesis of Stannylated IDT Donor Monomer

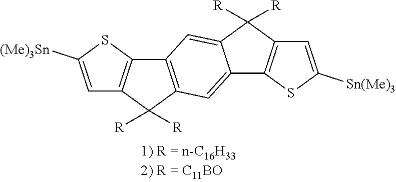

### General Procedure

Alkylated IDT (0.23 mmol) and a stir bar were added to a 10 mL Schlenk flask, evacuated and refilled with nitrogen three times. 2.5 mL of dry, degassed THF was added and the mixture was cooled to −78 C under nitrogen. n-BuLi (2.5 M in THF, 0.46 mL, 1.15 mmol) was added dropwise at −78 C and the reaction was stirred for 1 hour before warming to room temperature and stirring for 1 hour. The reaction was again cooled to −78 C and trimethyltin chloride (1.0 M in THF, 1.15 mmol, 1.15 mL). The reaction was warmed to room temperature and stirred overnight under nitrogen before quenching with water. The organic layer was diluted with hexanes and washed with water three times, dried over magnesium sulfate, filtered, and concentrated to give the final product as a pale yellow oil (375 mg, 90%).

1) n-C₁₆H₃₃ chain: ¹H NMR (600 MHz, THF-D₈) δ 7.28 (s, 2H), 7.01 (s, J_{H-Sn}=12 Hz, 2H), 1.96 (m, 4H), 1.86 (m, 4H), 0.96-1.36 (m, 112H), 0.69-0.83 (m, 12H) 0.40 (s, J_{H-Sn}=24 Hz, 9H);

2) C11-BO: ¹H NMR (600 MHz, THF-D₈) δ 7.28 (s, 2H), 7.01 (s, J_{H-Sn}=12 Hz, 2H), 1.96 (m, 4H), 1.86 (m, 4H), 0.96-1.36 (m, 160H), 0.69-0.83 (m, 12H) 0.40 (s, J_{H-Sn}24 Hz, 9H); ¹³C NMR (100 MHz, THF-D₈): δ 162.51, 159.01, 153.41, 145.06, 141.20, 134.47, 118.76, 58.45, 44.64, 43.01, 40.01, 39.20, 38.89, 37.45, 37.09, 35.64, 35.51, 35.31, 35.18, 34.87, 34.46, 32.21, 32.15, 30.58, 30.30, 30.19, 28.59, 28.12, 28.06, 19.07, −3.61.

### Synthesis of IDT-2F Donor-Acceptor Monomer

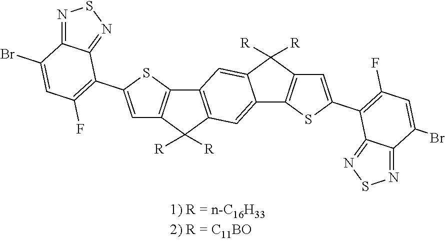

### Representative Procedure

In a glove box, 10 mL schlenk flask was charged with a stir bar, stannylated IDT donor (115.3 mg, 0.063 mmol), 4,7-dibromo-5-fluorobenzo[c][1,2,5]thiadiazole (50 mg, 0.16 mmol), and tetrakis triphenylphosphine palladium (0) (7.3 mg, 0.0063 mmol). 3 mL of dry, degassed xylenes was added, the reaction flask was sealed, removed from the glove box, and heated at 110 C for 96 hours under nitrogen. The reaction was cooled and concentrated, and the product was isolated via flash chromatography using 5% chloroform in hexanes as eluent. The product was recovered as a dark red oil (74.0 mg, 0.038 mmol, 60%). 1) n-C₁₆H₃₃ chain: ¹H NMR (600 MHz, CDCl₃) δ 8.07 (s, 2H), 7.76 (d, 2H), 7.40 (s, 2H), 2.09 (m, 4H), 1.95 (m, 4H), 0.96-1.36 (m, 112H), 0.69-0.83 (m, 12H).

2) C11-BO: ¹H NMR (600 MHz, CDCl₃) δ 8.07 (s, 2H), 7.76 (d, 2H), 7.40 (s, 2H), 2.09 (m, 4H), 1.95 (m, 4H), 0.96-1.36 (m, 112H), 0.69-0.83 (m, 12H); ¹³C NMR (100 MHz, CDCl₃): δ 167.94, 160.28, 156.50, 154.50, 153.99, 149.06, 145.17, 139.20, 136.05, 130.49, 123.78, 113.81, 54.44, 39.11, 37.39, 33.71, 33.34, 31.96, 30.16, 29.96, 29.82, 29.75, 29.71, 29.66, 29.61, 28.98, 26.73, 26.66, 24.26, 14.16.

HRMS (MALDI) m/z: calcd for C₁₁₆H₁₈₀S₄N₄Br₂F₂, 1959.190; found, 1959.1890.

### Polymerization (P2F-IDT)

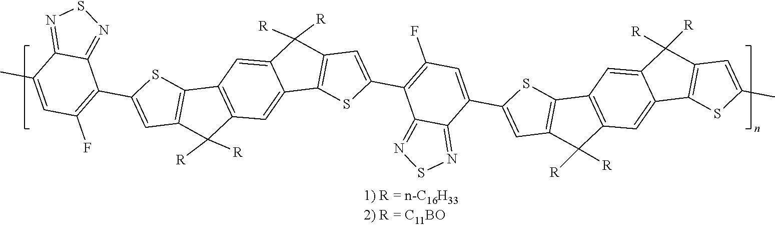

### Representative Procedure

A stir bar, IDT-2F donor-acceptor monomer (74.0 mg, 0.0376 mmol), stannylated IDT donor monomer (71.0 mg, 0.0388 mmol), and tetrakis triphenylphoshine plalladium (0) (3 mg, 0.00018 mmol) were added to a 5 mL microwave vial in the glove box. The vial was sealed and dry, degassed xylenes (2.5 mL) and dry, degassed DMF (0.2 mL) were added via syringe. The microwave vial was loaded into a microwave reactor and subjected to the following reaction conditions: 80° C. for 2 min, 130° C. for 2 min, 170° C. for 2 min and 200° C. for 40 min. The reaction was cooled to room temperature, then tributyl(thiophen-2-yl) stannane (20 μl) was added. The reaction was then subjected to the following reaction conditions in a microwave reactor: 80° C. for 2 min, 130° C. for 2 min, 170° C. for 2 min and 200° C. for 20 min. After the reaction was cooled to room temperature, 2-bromothiophene (20 μl) was added and the reaction was subjected to the following reaction conditions in a microwave reactor: 80° C. for 2 min, 130° C. for 2 min, 170° C. for 2 min and 200° C. for 20 min. The polymer solution was precipitated into methanol, filtered into a soxhlex thimble and washed in a soxhlet extractor with methanol (12 hours), ethyl acetate (4 hours) and the polymer was extracted with hexanes. The polymer was then purified on a silica gel column using chloroform as eluent. After concentration, 84 mg of polymer was recovered (70%) as a blue solid.

1) n-C₁₆H₃₃ chain: Mₙ=20 kDa, D=1.57

2) C₁₁-BO: Mₙ=39 kDa, D=2.0

### Polymerization (IDT-TTT)

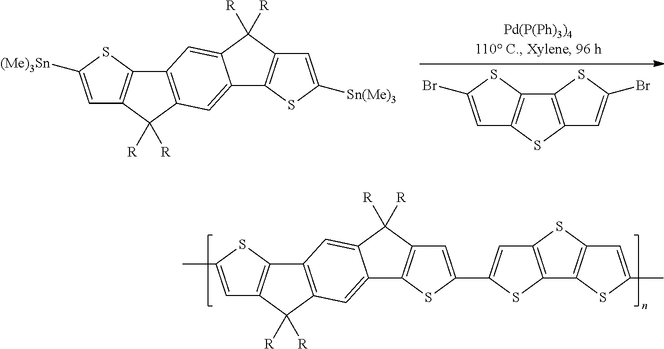

A stir bar, 2,6-dibromodithieno[3,2-b:2′,3′-d]thiophene (18.3 mg, 0.0517 mmol), stannylated IDT donor monomer (104.0 mg, 0.0569 mmol), and tetrakis triphenylphoshine plalladium (0) (6.6 mg, 0.00569 mmol) were added to a 5 mL schlenk flask in the glove box. The reaction was then stirred at 110 C under nitrogen for 96 hours. The polymer solution was precipitated into methanol, filtered into a soxhlex thimble and washed in a soxhlet extractor with methanol (12 hours), ethyl acetate (4 hours) and the polymer was extracted with chloroform. The polymer was then purified on a silica gel column using chloroform as eluent. After concentration, 36 mg of polymer was recovered (41%) as a purple solid.

R=C11-BO: Mₙ=15 kDa, D=1.5

Since IDT-TTT is a donor-donor polymer rather than a donor-acceptor polymer, it has a wider bandgap, but similar absorption profiles to other liquid crystals we have made, exhibiting a narrow low energy absorption due to π-stacking in both thin film and solution. There was no solvent dependency on the shape of absorption, nor did annealing change the relative intensities of the peaks. Polarized optical microscopy showed this material is not birefringent, and is likely not a liquid crystal.

### 6. Process Steps

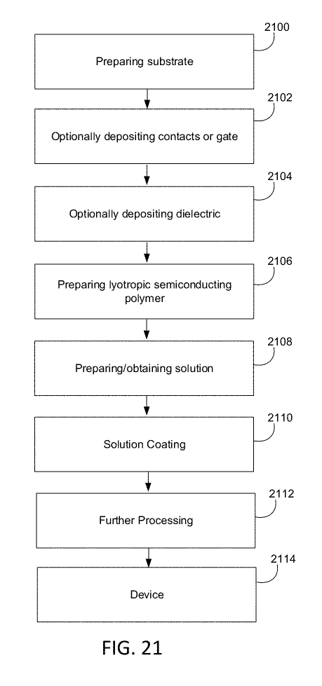

FIG. 21 is a flowchart illustrating a method for fabricating a film or device such as an OFET. The method leverages selective solubility of polymers (e.g., that are typically amorphous) to access lyotropic liquid crystalline mesophases and make highly crystalline films of donor-acceptor conjugated polymers.

The method can comprise the following steps.

### a. Substrate Preparation

Block 2100 represents obtaining/providing and/or preparing a substrate. In one or more embodiments, the substrate comprises a flexible substrate. Examples of a flexible substrate include, but are not limited to, a plastic substrate, a polymer substrate, a metal substrate, or a glass substrate. In one or more embodiments, the flexible substrate is at least one film or foil selected from a polyimide film, a polyether ether ketone (PEEK) film, a polyethylene terephthalate (PET) film, a polyethylene naphthalate (PEN) film, a polytetrafluoroethylene (PTFE) film, a polyester film, a metal foil, a flexible glass film, and a hybrid glass film. In one or more embodiments, the substrate is a swellable substrate.

### b. Contact Deposition

Block 2102 represents optionally forming/depositing contacts or electrodes (e.g., p-type, n-type contacts, a gate, a source, and/or drain contacts) on or above (or as part of) the substrate.

In an OFET embodiment comprising a top gate & bottom contact geometry, source and drain contacts are deposited on the substrate. Examples of materials for the source and drain contacts include, but are not limited to, gold, silver, silver oxide, nickel, nickel oxide (NiOx), molybdenum, and/or molybdenum oxide. In one or more embodiments, the source and drain contacts of the OFET further comprise a metal oxide electron blocking layer, wherein the metal in the metal oxide includes, but is not limited to, nickel, silver, or molybdenum.

In an OFET embodiment comprising a bottom gate geometry, a gate electrode is deposited on the substrate. In one or more embodiments, the gate contact (gate electrode) is a thin metal layer. Examples of the metal layer for the gate include, but are not limited to, an aluminum layer, a copper layer, a silver layer, a silver paste layer, a gold layer or a Ni/Au bilayer. Examples of the gate contact further include, but are not limited to, a thin Indium Tin Oxide (ITO) layer, a thin fluorine doped tin oxide (FTO) layer, a thin graphene layer, a thin graphite layer, or a thin PEDOT:PSS layer. In one or more embodiments, the thickness of the gate electrode is adjusted (e.g., made sufficiently thin) depending on the flexibility requirement.

The gate, source, and drain contacts can be printed, thermally evaporated, or sputtered, for example.

### c. Dielectric Formation

Block 2104 represents optionally depositing a dielectric on the gate electrode, e.g., when fabricating an OFET in a bottom gate configuration. In this example, the dielectric is deposited on the gate contact's surface to form a gate dielectric.

Examples of depositing the dielectric include forming a coating including one or one or more dielectric layers on the substrate (and selecting a thickness of the dielectric layers or coating). In one or more examples, the dielectric is structured or patterned, e.g., to form nanogrooves or nanostructures in the dielectric. Examples of dimensions for the nanogrooves include, but are not limited to, a nanogroove depth of 6 nanometers or less and/or a nanogroove width of 100 nm or less.

Examples of dielectric layers include, but are not limited to, a single polymer (e.g., PVP, polyimide) dielectric layer or multiple dielectric layers (e.g., bilayer dielectric). A single polymer dielectric layer may be preferred in some embodiments (for easier processing, or for more flexibility). In one embodiment, the dielectric layer comprises silicon dioxide (SiO₂). In another embodiment, the dielectric layers form a polymer/SiO₂ bilayer. In yet another embodiment, the dielectric layers form a polymer dielectric/SiO₂/SAM multilayer with the SiO₂ on the polymer and the alkylsilane or arylsilane Self Assembled Monolayer (SAM) layer on SiO₂. In yet a further embodiment, the dielectric layers form a SiO₂/SAM bilayer with the alkylsilane or arylsilane SAM layer on the SiO₂. Various functional groups may be attached to the end of the alkyl groups to modify the surface property of the SAM layer.

The thickness of the SiO₂ may be adjusted (e.g., made sufficiently thin) depending on the composition of the dielectric layers and the flexibility requirement. For example, in one embodiment, the dielectric layer might not include a polymer dielectric layer and still be flexible.

In one or more embodiments, the nanogrooves/nanostructures are formed/patterned using nano imprint lithography. In one example, patterning the dielectric layers comprises nano-imprinting a first dielectric layer (e.g., PVP) deposited on a gate metal surface of the substrate; and depositing a second dielectric layer on the nanoimprinted first dielectric layer, wherein a thickness of the second dielectric layer (e.g., comprising SiO₂) is adjusted.

In another example, the grooves are formed by rubbing the dielectric with an abrasive or with a cloth (e.g., velvet cloth).

In one or more examples, the lyotropic semiconducting polymers are disposed on, and aligned with, grooves on a dielectric layer and the dielectric layer comprises polyimide having a thickness between 25 nm and 200 nm.

### d. Semiconducting Polymer Synthesis

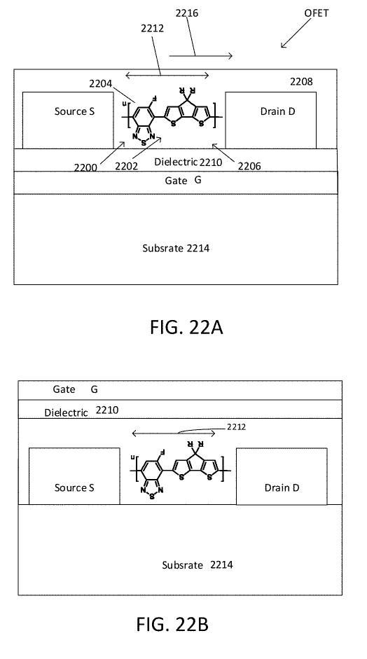

Block 2106 (referring also to FIGS. 22A-22B) represents preparing/obtaining a composition of matter comprising lyotropic semiconducting polymers 2200 each having a donor-acceptor copolymer backbone 2202 and a side chain 2204 attached to the backbone 2202, wherein the donor-acceptor copolymer backbone 2202 comprises fused aromatic rings.

In one or more embodiments, the backbone 2202 is selected to be sufficiently rigid to form a crystalline structure in solution.

In one or more embodiments, the semiconducting polymer has the repeating unit structure [Dₐ-D_{b}]ₙ, [D-A]ₙ or [D-A-D-A]ₙ wherein D, Dₐ, D_{b} comprises the donor, A comprises the acceptor, and n is an integer representing the number of repeating units. In one or more embodiments, the structure has a regioregular conjugated main chain section having n=5-150, or more, contiguous repeat units. In some embodiments, the number of repeat units n is in the range of 10-40 repeats. The regioregularity of the conjugated main chain section can be 95% or greater, for example.

### (i) Side Chain Selection

The step further comprises selecting side chains 2204, R for the semiconducting polymers 2200, e.g., side chains 2204 that dissolve in a solvent more effectively than the backbone 2202. Examples include branched side-chains having a size sufficiently large to form a lyotropic mesophase in a solvent, e.g., a branched side-chain comprising a C₃-C₅₀, C₅-C₅₀, C₈-C₅₀, or C₉-C₅₀ substituted or non-substituted alkyl chain.

Examples of branched alkyl chains include isopropyl, sec-butyl, t-butyl, 1,2-dimethylpropyl, 1,1-dimethyl-propyl, 4-methylpentyl, 1-methylpentyl, 2-methylpentyl, 3-methylpentyl, 1,1-dimethylbutyl, 2,2-dimethylbutyl, 3,3-dimethylbutyl, 1,2-dimethylbutyl, 1,3- dimethylbutyl, 1,2,2-trimethylpropyl, 1,1,2-trimethylpropyl, 5-methylhexyl, 1-methylhexyl, 2,2-dimethylpentyl, 3,3-dimethylpentyl, 4,4-dimethylpentyl, 1,2-dimethylpentyl, 1,3-dimethylpentyl, 1,4-dimethylpentyl, 1,2,3-trimethylbutyl, 1,1,2-trimethylbutyl, 1,1,3-trimethylbutyl, 6-methylheptyl, 1-methylheptyl, 1,1,3,3-tetramethylbutyl, 1-, 2-, 3-, 4-, 5-, 6- or 7-methyloctyl, 1-, 2-, 3-, 4- or 5-ethylheptyl, 1 -, 2- or 3-propylhexyl, 1-, 2-, 3-, 4-, 5-, 6-, 7- and 8-methylnonyl, 1-, 2-, 3-, 4-, 5- or 6-ethyloctyl, 1-, 2-, 3- or 4-propylheptyl, dimethyloctyl, 1-, 2-, 3-, 4-, 5-, 6-, 7-, 8- or 9-methyldecyl, 1-, 2- , 3-, 4-, 5-, 6- or 7-ethylnonyl, 1-, 2-, 3-, 4- or 5-propyloctyl, 1-, 2- or 3-butylheptyl, 1-pentylhexyl, 1-, 2-, 3-, 4-, 5-, 6-, 7-, 8-, 9- or 10-methylundecyl, 1-, 2-, 3-, 4-, 5-, 6-, 7- or 8- ethyldecyl, 1-, 2-, 3-, 4-, 5- or 6-propylnonyl, 1-, 2-, 3- or 4-butyloctyl, 1-, 2-pentylheptyl, branched butyl, pentyl, hexyl, heptyl, octyl, nonyl, decyl, undecyl, dodecyl, tridecyl, tetradecyl, pentadecyl, hexadecyl, heptadecyl, octadecyl, nonoadecyl, eicosyl with one or more branch points at any carbon of the alkyl chain, such as 2 (or 1, or 3, or 4)-ethylhexyl, 2 (or 1, or 3, or 4)-hexyldecyl, 2 (or 1, or 3, or 4)-octyldodecyl, 2 (or 1 or 3, or 4)-butyloctyl, 4 (or 1, or 2, or 3, or 5, or 6)-butyldecyl, 5 (or 1, or 2, or 3, or 4, or 6, or 7)-butylundecyl, 6 (or 1, or 2, or 3, or 4, or 5, or 7, or 8)-butyldodecyl, 12 (or 1, or 2, or 3, or 4, or 5, or 6, or 7, or 8, or 9, or 10, or 11, or 13, or 14)-butyloctadecyl, and the like.

The side chain includes a branched chain having a branching point (e.g., first branch point closest to the backbone) positioned more than one atom along the side chain from the copolymer backbone. The more than one atom (atom at the branching point or atoms in the side chain) can be carbon or a heteroatom such as, but not limited to, boron, silicon, germanium, nitrogen, phosphorous, oxygen, sulfur, selenium, or include any combination thereof.

One or more of any of the carbons in the side chain can be replaced by any of the heteroatoms listed, while the number of hydrogens attached need to be adjusted to match the valence of the heteroatoms, except O, S, Se cannot replace the branch CH since the branch atom needs to be at least tri-valent. Heteroatoms can be anywhere in the side chain (except that divalent atoms like O, S, Se cannot be the branched atom) e.g., 4-butyldecyl(—CH₂CH₂CH₂CH(C₄H₉)C₆H₁₃).

In one or more examples, the side chain includes a branched chain having a branching point positioned more than one (e.g., carbon) atom along the side chain from the copolymer backbone. In one or more examples, the side chain includes a branched alkyl, aryl or alkoxy side chain having a branching point positioned more than one (e.g., carbon) atom from the backbone and along the side chain. In one or more examples, the branching point is positioned between 2 and 20 carbon atoms from the backbone and along the side chain.

In one or more examples, there is more than one branch (one or more branch points) in one side chain, as illustrated by the branched side chain examples on pages 38-39. Each branch may comprise a substituted or non-substituted alkyl, aryl or alkoxy chain with 1 to 20 carbons. There may be 0, 1, 2, 3 or more carbons or heteroatoms separate the branch points

The branched alkyl chain may optionally include a carbon chiral center, and the branched alkyl chain is enantiopure or enantioenriched.

In one or more examples, the side chains have a structure/composition selected to reduce steric repulsion between side chains and increase attraction between the backbones in adjacent semiconducting polymers.

In one or more further examples, the side chains have a structure/composition such that the side chains extend more towards a direction parallel to the backbone than towards a direction perpendicular to the backbone. For example, the side chains may be in plane with the backbone to increase intermolecular interactions and pi-pi stacking between the semiconducting polymers and increase alignment of the semiconducting polymers, as compared to side chains that are out of plane with the backbone that reduce the intermolecular interactions and do not align the semiconducting polymers as well).

In one or more examples, the side chains are connected to the backbone via a double bond that is incapable of rotating about an axis connecting the side chain to the backbone.

In one or more examples, there are two side chains connected to the same carbon (or heteroatom listed above) in the backbone.

### (ii). Donor-Acceptor Semiconducting polymers

Examples of the donor in the repeat unit 2206 include dithiophenes having the structure:

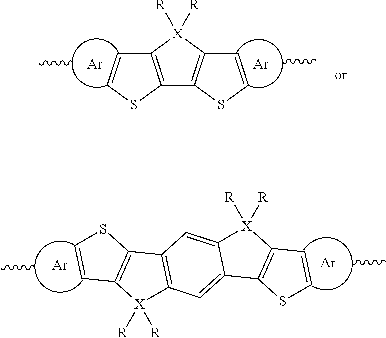

wherein each Ar is independently a substituted or non-substituted aromatic functional group (or each Ar is independently nothing and the valence of its respective thiophene ring is completed with hydrogen), each R is independently hydrogen or a substituted or non-substituted alkyl, aryl, or alkoxy chain (having the branched structure and composition described herein to achieve a lyotropic mesophase), and X is C, C═C, Si, Ge, N or P. The R groups can be the same or different. In the dithiophene, the R comprising the substituted or non-substituted alkyl, aryl or alkoxy chain can be a branched C₃-C₅₀ substituted or non-substituted alkyl or alkoxy chain, —(CH₂CH₂O)n (n=2˜20), C₆H₅, —CₙF₍₂ₙ₊₁₎ (n=2˜20), —(CH₂)ₙN(CH₃)₃Br (n=2˜20), 2-ethylhexyl, 2-hexyldecyl, 2-octyldodecyl, 2-butyloctyl, 4-butyldecyl, 5-butylundecyl, 6-butyldodecyl, 12-butyloctadecyl, PhCₘH₂ₘ₊₁ (m=1-20), —(CH₂)ₙN(C₂H₅)₂ (n=2˜20), —(CH₂)ₙSi(CₘH₂ₘ₊₁)₃ (m, n=1 to 20), or —(CH₂)ₙSi(CₘH₂ₘ₊₁)₃)ₓ(CₚH₂ₚ₊₁)_{y} (m, n, p=1 to 20, x+y=3).

For example, the dithiophene unit could comprise:

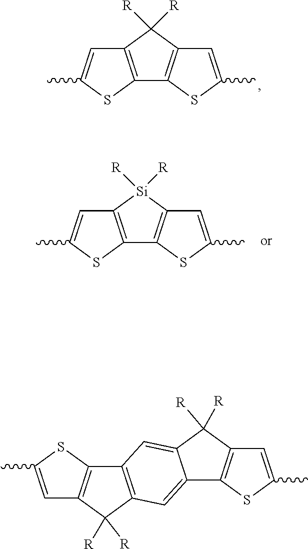

In one or more embodiments, the repeat unit further comprises an acceptor attached to the donor, the acceptor including a pyridine of the structure:

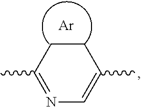

wherein Ar is a substituted or non-substituted aromatic functional group, or Ar is nothing and the valence of the pyridine ring is completed with hydrogen. In one or more embodiments, the pyridine is regioregularly arranged along the conjugated main chain section.

Examples of the pyridine unit include, but are not limited to:

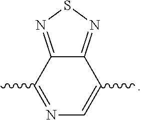

In one or more embodiments, the repeat unit further comprises an acceptor attached to the donor, comprising the structure:

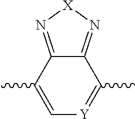

wherein X is O, S, Se, or N—R where R is H or a substituted or non-substituted alkyl, aryl or alkoxy chain; and Y is either C or N.

Thus, in one or more embodiments, combination of the pyridine and the dithiophene yields the polymer of the formula:

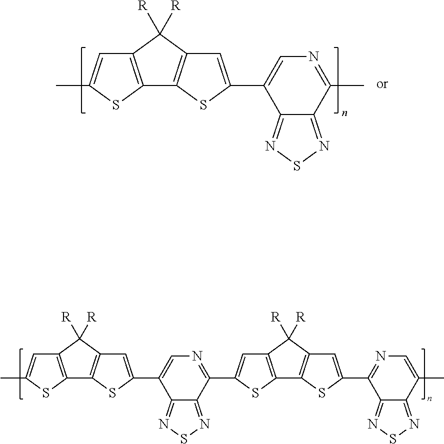

wherein the R has the branched structure and composition to achieve the lyotropic mesophase in solution as described herein.

In one or more further examples, the acceptor A comprises an aromatic ring comprising a side group (e.g., Fluorine) having reduced susceptibility to oxidization as compared to a pyridine ring (e.g., a regioregular fluoro-phenyl unit). For example, the acceptor has the structure:

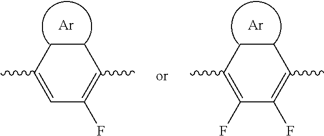

wherein Ar is a substituted or non-substituted aromatic functional group containing one, two, three or more aromatic rings, or Ar is nothing and the valence of the ring comprising fluorine (F) is completed with hydrogen. In one or more embodiments, the ring comprising F is regioregularly arranged along the conjugated main chain section.

In one or more embodiments, the repeat unit further comprises an acceptor attached to the donor, comprising the structure:

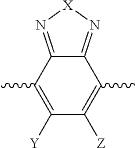

wherein X is O, S, Se, or N—R where R is H or a substituted or non-substituted alkyl, aryl or alkoxy chain; and Y and Z are independently selected to be H or F.

In one or more examples, the ring comprising the F has the structure:

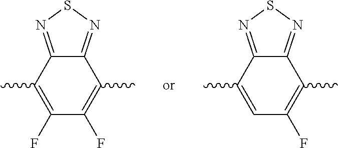

Other examples include those illustrated in FIG. 6a of U.S. patent application Ser. No. 15/349,908 entitled “FLUORINE SUBSTITUTION INFLUENCE ON BENZO[2,1,3]THIODIAZOLE BASED POLYMERS FOR FIELD-EFFECT TRANSISTOR APPLICATIONS,” Attorney's Docket No. 30794.607-US-U1 (UC REF 2016-316) (which application is incorporated by reference herein and cross-referenced above).

In one or more embodiments, the donor (connected to the fluorinated acceptor in the repeat unit) is a dithiophene as described previously.

Thus, in one or more embodiments, the semiconducting polymer is a regioregular semiconducting polymer comprising a repeating unit of the structure:

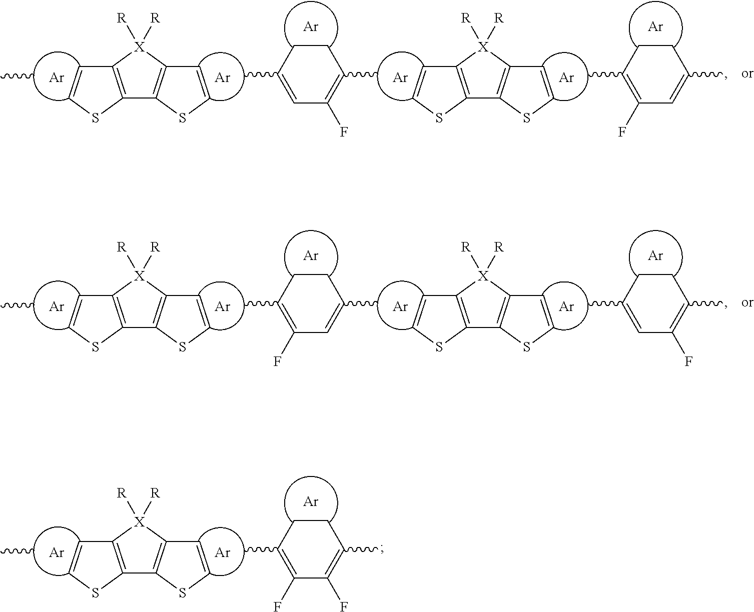

More specific examples include:

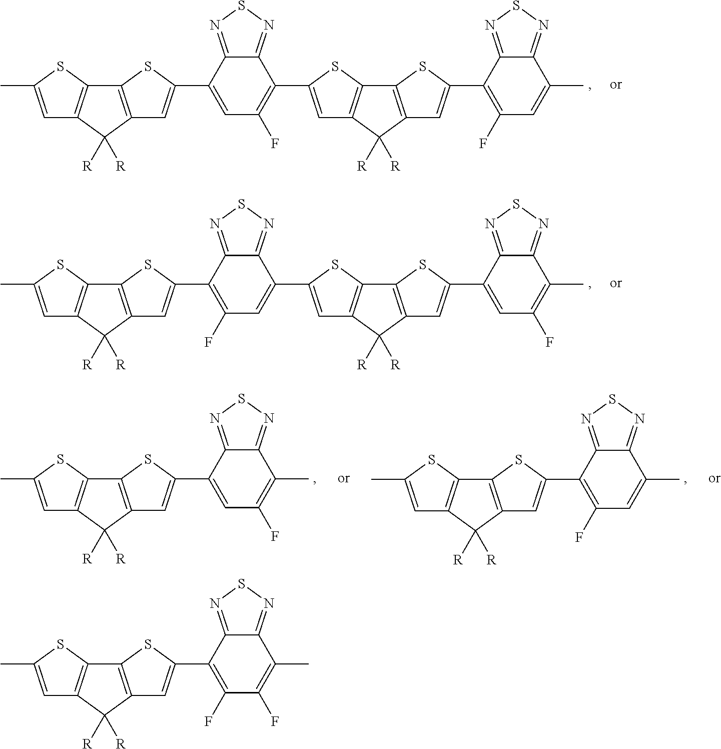

where the ring comprising F is regioregularly arranged along the conjugated main chain section pointing toward the direction shown in the structures above, Ar is a substituted or non-substituted aromatic functional group containing one, two, three or more aromatic rings, or Ar is nothing and the valence of the ring comprising fluorine (F) or the valence of the dithiophene is completed with hydrogen, and the R groups are the side chains 2204 having the branched structure and composition to achieve the lyotropic mesophase in solution as described herein (e.g., branched substituted or non-substituted alkyl, aryl or alkoxy chain are a C₆-C₅₀ substituted or non-substituted alkyl or alkoxy chain, comprising —(CH₂CH₂O)n (n=2˜20), C₆H₅, —CₙF₍₂ₙ₊₁₎ (n=2˜20), —(CH₂)ₙN(CH₃)₃Br (n=2˜20), 2-ethylhexyl, 2-hexyldecyl, 2-octyldodecyl, 2-butyloctyl, 4-butyldecyl, 5-butylundecyl, 6-butyldodecyl, 12-butyloctadecyl, PhCₘH₂ₘ₊₁ (m=1-20), —(CH₂)ₙN(C₂H₅)₂ (n =2˜20), —(CH₂)ₙSi(CₘH₂ₘ₊₁)₃ (m, n=1 to 20), or —(CH₂)ₙSi(OSi(CₘH₂ₘ₊₁)₃)ₓ(CₚH₂ₚ₊₁)_{y} (m, n, p=1 to 20, x+y=3).

Examples include branched side-chains having a size sufficiently large to form a lyotropic mesophase in a solvent, e.g., a branched side-chain comprising a C₃-C₅₀, C₅-C₅₀, C₈-C₅₀ or C₉-C₅₀ substituted or non-substituted alkyl chain. Examples of branched alkyl chains include isopropyl, sec-butyl, t-butyl, 1,2-dimethylpropyl, 1,1-dimethyl-propyl, 4-methylpentyl, 1-methylpentyl, 2-methylpentyl, 3-methylpentyl, 1,1-dimethylbutyl, 2,2-dimethylbutyl, 3,3-dimethylbutyl, 1,2-dimethylbutyl, 1,3- dimethylbutyl, 1,2,2-trimethylpropyl, 1,1,2-trimethylpropyl, 5-methylhexyl, 1- methylhexyl, 2,2-dimethylpentyl, 3,3-dimethylpentyl, 4,4-dimethylpentyl, 1,2- dimethylpentyl, 1,3-dimethylpentyl, 1,4-dimethylpentyl, 1,2,3-trimethylbutyl, 1,1,2-trimethylbutyl, 1,1,3-trimethylbutyl, 6-methylheptyl, 1-methylheptyl, 1,1,3,3-tetramethylbutyl, 1-, 2-, 3-, 4-, 5-, 6- or 7-methyloctyl, 1-, 2-, 3-, 4- or 5- ethylheptyl, 1-, 2- or 3-propylhexyl, 1-, 2-, 3-, 4-, 5-, 6-, 7- and 8- methylnonyl, 1-, 2-, 3-, 4-, 5- or 6-ethyloctyl, 1-, 2-, 3- or 4-propylheptyl, dimethyloctyl, 1-, 2-, 3-, 4-, 5-, 6-, 7-, 8- or 9-methyldecyl, 1-, 2-, 3-, 4-, 5-, 6- or 7-ethylnonyl, 1-, 2-, 3-, 4- or 5-propyloctyl, 1-, 2- or 3-butylheptyl, 1-pentylhexyl, 1-, 2-, 3-, 4-, 5-, 6-, 7-, 8-, 9- or 10- methylundecyl, 1-, 2-, 3-, 4-, 5-, 6-, 7- or 8-ethyldecyl, 1-, 2-, 3-, 4-, 5- or 6-propylnonyl, 1-, 2-, 3- or 4-butyloctyl, 1-, 2-pentylheptyl, branched butyl, pentyl, hexyl, heptyl, octyl, nonyl, decyl, undecyl, dodecyl, tridecyl, tetradecyl, pentadecyl, hexadecyl, heptadecyl, octadecyl, nonoadecyl, eicosyl with one or more branch points at any carbon of the alkyl chain, such as 2 (or 1, or 3, or 4)-ethylhexyl, 2 (or 1, or 3, or 4)-hexyldecyl, 2 (or 1, or 3, or 4)-octyldodecyl, 2 (or 1 or 3, or 4)-butyloctyl, 4 (or 1, or 2, or 3, or 5, or 6)-butyldecyl, 5 (or 1, or 2, or 3, or 4, or 6, or 7)-butylundecyl, 6 (or 1, or 2, or 3, or 4, or 5, or 7, or 8)-butyldodecyl, 12 (or 1, or 2, or 3, or 4, or 5, or 6, or 7, or 8, or 9, or 10, or 11, or 13, or 14)-butyloctadecyl, and the like.

The branched alkyl chain may optionally include a carbon chiral center, and the branched alkyl chain is enantiopure or enantioenriched.

For example, the semiconducting polymer can be regioregular poly[5-fluoro-[2,1,3]benzothiadiazole-4,7-diyl(4,4-dialkyl-4H-cyclopenta[2,1-b:3,4- b′]dithiophene-2,6diyl)-5-fluoro-[2,1,3]benzothiadiazole-7,4-diyl(4,4-dialkyl-4H-cyclopenta[2,1-b:3,4-b′]dithiophene-2,6- diyl)] (P2F or PCDTFBT). The alkyl group is a branched alkyl side-chain comprising a C₃-C₅₀, C₅-C₅₀, C₈-C₅₀, or C₉-C₅₀ substituted or non-substituted alkyl chain.

Further examples of the fluorophenylene as the acceptor include fluorphenylene units having the structural formula:

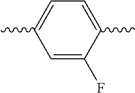

2-fluoro-1,4-phenylene,

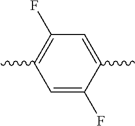

2,5-difluoro-1,4-phenylene,

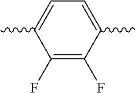

2,3-difluoro-1,4-phenylene,

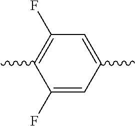

2,6-difluoro-1,4-phenylene,

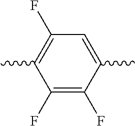

2,3,5-trifluoro-1,4-phenylene, or

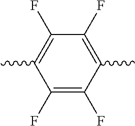

2,3,5,6-tetrafluoro-1,4-phenylene.

The 2-fluoro-1,4-phenylene, 2,6-difluoro-1,4-phenylene, and 2,3,5-trifluoro-1,4-phenylene may form regioregular polymers, whereas the other fluorophenylenes (2,5-difluoro-1,4-phenylene, 2,3-difluoro-1,4-phenylene, and 2,3,5,6-tetrafluoro-1,4-phenylene) do not.

In one or more examples, the phenylene comprising F is regioregularly arranged along the conjugated main chain section (e.g., pointing toward the direction shown in the structures above), the R groups are the side chains 2204 having the branched structure and composition to achieve the lyotropic mesophase in solution as described herein (e.g., a branched substituted or non-substituted alkyl, aryl or alkoxy chain comprising, for example, a C₆-C₃₀ substituted or non-substituted alkyl or alkoxy chain, —(CH₂CH₂O)n (n=2˜20), C₆H₅, —CₙF₍₂ₙ₊₁₎ (n=2˜20), —(CH₂)ₙN(CH₃)₃Br (n=2˜20), 2-ethylhexyl, 2-hexyldecyl, 2- octyldodecyl, 2-butyloctyl, 4-butyldecyl, 5-butylundecyl, 6-butyldodecyl, 12-butyloctadecyl, PhCₘH₂ₘ₊₁ (m=1-20), —(CH₂)ₙN(C₂H₅)₂ (n=2˜20), —(CH₂)ₙSi(CₘH₂ₘ₊₁)₃ (m, n=1 to 20), or —(CH₂)ₙSi(OSi(CₘH₂ₘ₊₁)₃)ₓ(CₚH₂ₚ₊₁)_{y} (m, n, p=1 to 20, x+y=3).

Other examples of regioregular structures include those described above but with the 2-fluoro-1,4-phenylene replaced with 2,6-difluoro-1,4-phenylene or 2,3,5-trifluoro-1,4-phenylene.

Further example regioregular structures include:

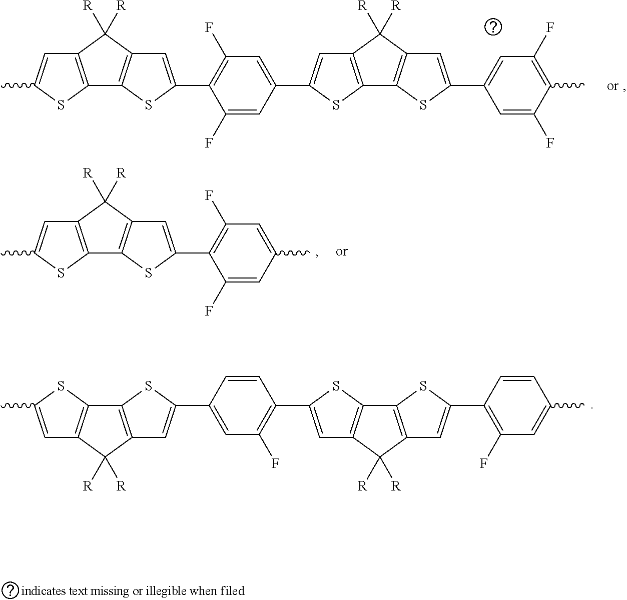

Examples of non-regioregular structures include:

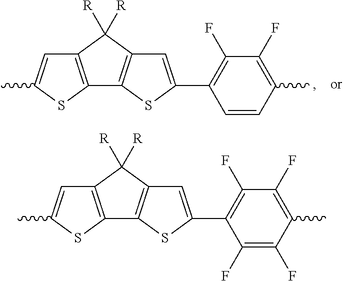

wherein the R groups are the side chains 2204 having the branched structure and composition to achieve the lyotropic mesophase in solution as described herein.

### (iii) Indacenodithiophene P2F (P2F-IDT) Copolymers with Extended and Rigid Donor Units

In another example, the semiconducting polymer is synthesized with the following structure:

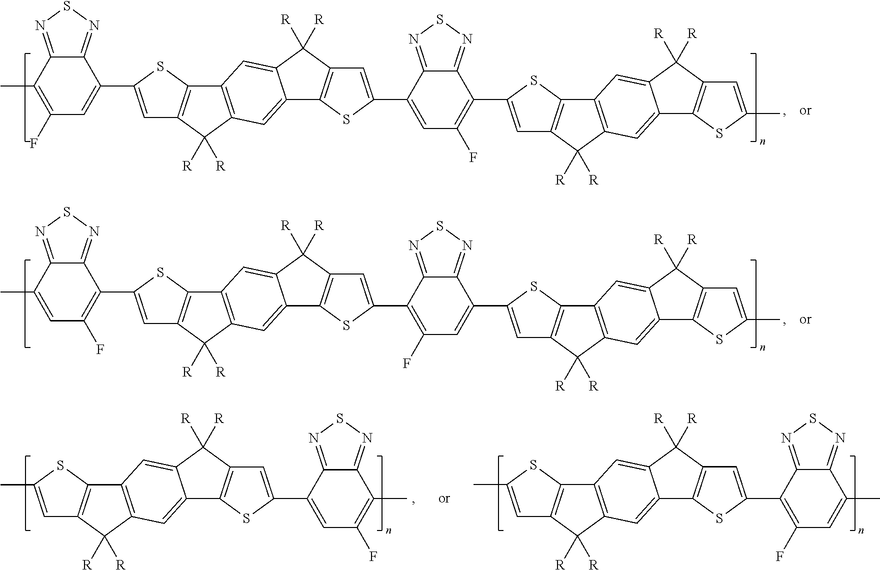

wherein R is a branched side chain as described in 6 d. (i) above.

### (iv) Donor-Donor Semiconducting Polymers

Further examples include a polymer with a rigid donor (e.g., indacenodithiophene) paired with another rigid donor (e.g., dibromodithieno[3,2-b:2′,3′-d]thiophene). In one example, the polymer is IDT-TTT having the structure:

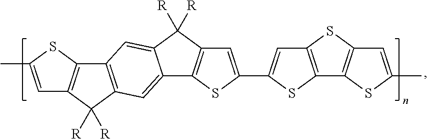

wherein R is a branches side chain as described in 6. d (i) above.

### e. Preparation of Lyotropic Solution

Block 2108 represents preparing/obtaining a lyotropic solution comprising a solvent and the side chains dissolved in the solvent, e.g., wherein the semiconducting polymers are disposed in a lyotropic liquid crystalline mesophase). The step can comprise selecting a selective solvent for the side chains; and combining the semiconducting polymers and the selective solvent so that the lyotropic solution is formed.

The solvent (e.g., hexane, chloroform or chlorobenzene) used in the solution is selected to form the semiconducting polymers exhibiting the lyotropic mesophase. In one or more embodiments, the solvent in the lyotropic solution is a selective solvent that has a propensity to dissolve the side chain (e.g., the solvent dissolves the side chains more effectively than the backbone of the semiconducting polymers, or the solvent selectively dissolves the side chains but not the backbone). The selective solvent can be a hydrocarbon (e.g., a substituted or non-substituted alkanes, alkenes, alkynes, aromatics, ethers, esters, alcohols, halides, aldehydes, ketones, amines, amides), water, or a mixture of above.

In one or more embodiments, a fabricated liquid crystal mesophase is present at all concentrations of the lyotropic solution.

Molecular structure can be varied to obtain desirable thermodynamic mesophase parameters.

In one or more embodiments, differential solvent interactions with the semiconducting polymers are selected to make amphiphilic structures that form ordered aggregates, e.g., similar to micellation.

In one example, the lyotropic solution includes the lyotropic semiconducting polymers stacked into a crystalline structure (see, e.g., ultraviolet-visible (UV-Vis) absorption data and X-ray diffraction data presented herein), e.g., as characterized by having a thermal transition expected for a crystalline transition (e.g., as measured by DSC).

In one or more embodiments, a further process is included to give the polymer solution enough activation energy to break up kinetically trapping disordered polymer aggregates, allows the thermodynamically favorable crystalline structures (lyotropic liquid crystalline mesophases) to form by self assembly. Processes include solution annealing, by heating the solution to a certain temperature (e.g. 125° C.), then cool down slowly (e.g. at 1° C./minute); or by solution sonication; or first dissolve the polymer in a mixture of good and poor solvents then selectively (partially) remove the good solvent; or first dissolve the polymer in a good solvent then add certain amount of poor solvent to induce the lyotropic liquid crystalline mesophases.

### f. Solution Casting

Block 2110 represents solution casting/processing the lyotropic solution comprising the semiconducting copolymer(s) (e.g., onto the dielectric) to form a film comprising the semiconducting copolymer(s), so that the the semiconducting polymers are deposited from the lyotropic solution comprising the semiconducting polymers in a lyotropic liquid crystalline mesophase.

In one or more embodiments, the lyotropic solution is coated onto the substrate using an equilibrium coating method.

Solution casting methods include, but are not limited to, inkjet printing, bar coating, spin coating, blade coating, spray coating, roll coating, dip coating, free span coating, dye coating, screen printing, and drop casting.

### g. Further Processing

Block 2112 represents further processing the polymer film cast on the patterned dielectric layers. The step can comprise annealing/curing the film or allowing the film to dry. The step can comprise depositing source and drain contacts as described above, if necessary.

In one or more embodiments, a solid state film is formed comprising the lyotropic semiconducting polymers combined in a stack and pi-pi bonds between the lyotropic semiconducting polymers. In one or more examples, the lyotropic semiconducting polymers at a top of the film are aligned with the semiconducting polymers at a bottom of the film. In one or more embodiments, intermolecular interactions between the lyotropic semiconducting polymers are controlled and increased/enhanced to achieve high alignment of the semiconducting polymers in the solid state.

### h. Example Device Structures

Block 2114 represents the end result, a device or film/composition of matter useful in a device.

FIG. 22A and 22B illustrate OFETs comprising an active region comprising aligned donor-acceptor copolymers 2200 each comprising a main chain section or backbone 2202 including fused aromatic rings and a side chain 2204, the main chain section 2202 having a repeat unit 2206 that comprises at least one donor D (e.g., as described in Block 2106) and at least one acceptor A (as described in Block 2106).

In various examples, the semiconducting polymers comprise lyotropic semiconducting polymers. In one or more examples, a lyotropic solution includes the lyotropic semiconducting polymers aligned in a liquid crystal. In one or more examples, the semiconducting polymers are amphiphilic semiconducting polymers, and the side chains dissolve in a solvent more effectively than the backbone. Example solvents include, but are not limited to, at least one compound selected from an alkane, an alkene, an alkyne, an ether, an ester, an alcohol, a halide, an aldehyde, a ketone, an amine, an amide, and water.

The OFET further comprises a source contact S and a drain contact D to a the semiconducting polymer 2200 or a film 2208 comprising the semiconducting polymer 2200, wherein the source S and drain D are separated by a length of a channel; and a gate connection/contact G on a dielectric 2210, wherein the gate connection G applies a field to the semiconducting polymer 2200 across the dielectric 2210 between the polymer 2200 and the gate G to modulate conduction along the semiconducting polymer 2200 in a channel between the source contact S and the drain contact D, thereby switching the OFET on or off.

In one or more embodiments, the OFET comprises means (e.g., formation of liquid crystals and shear forces applied to the liquid crystals, or statutory equivalents thereof) for aligning the polymer 2200 to the channel. The liquid crystals can be oriented/aligned so that the semiconducting polymers 2200 each have their backbone/main chain axis 2202 aligned with an alignment direction 2212 in the channel pointing from the source contact S to the drain contact D, so that charge transport between the source S and the drain D is preferentially along the alignment direction 2212. Conduction between the source contact S and the drain contact D is predominantly along the backbones/main chain axes 2202, although charge hopping between adjacent polymers in the liquid crystal is also possible. For example, the means can align the backbones 2202 to an imaginary line bounded by/alignment direction between the source S and the drain D. The source and drain can be positioned such that a minimum distance between the source contact and drain contact is substantially parallel to the alignment direction 2212 of the backbones 2202.

In one or more embodiments, shear coating (e.g. blade coating), dip coating, and bar coating (or statutory equivalents thereof) is used to coat the semiconducting polymers 2200 on dielectric 2210 or substrate 2214. For example, the solution processing can include coating the lyotropic solution onto the substrate by applying a shear force/field 2216 to the lyotropic solution, wherein increased intermolecular interactions between the semiconducting polymers (tailored using the side chains 2204 and/or the selective solvent) increase the effectiveness of shear alignment of the semiconducting polymers caused by the shear force/field 2216. In one or more embodiments, the shear force 2216 is applied with a blade having a larger area (e.g., more than a single contact point) of contact with the lyotropic solution so as to increase a period of time and/or distance the lyotropic solution is in the shear field/force 2216.

Embodiments of the present invention are not limited to the particular sequence of depositing the source, drain, and gate contacts. For example, OFETs according to one or more embodiments of the present invention can be fabricated in a bottom gate & top contact geometry, bottom gate & bottom contact geometry, top gate & bottom contact geometry, and top gate & top contact geometry.

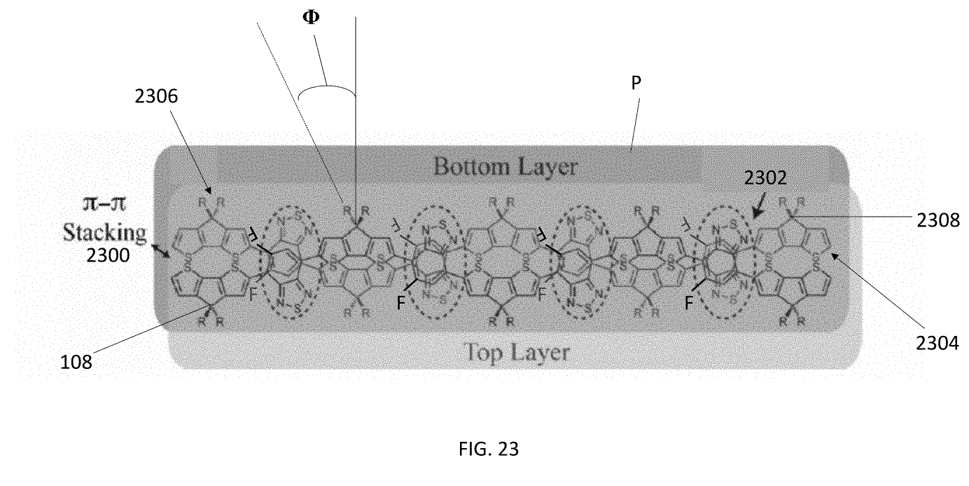

FIG. 23 (referring also to FIGS. 1A-1E and 22A-22B) illustrates lyotropic semiconducting polymers 2302 each having a backbone 2202 and a side chain 2204 attached to the backbone 2202, wherein the side chain 2204 includes a branched chain R having a branching point 100 positioned more than one atom 102 from the backbone 2202 and along the side chain 2204, and the branching point 100 is the first or closest branching point to the backbone 2202. The branched side chains R disrupt pi-pi stacking 2300 (between the lyotropic semiconducting polymers 2302 comprising fused aromatic rings 2304) and that the branched side chains R extend outside a plane P containing the fused aromatic rings 2304. In the example illustrated in FIG. 23, a pair 2306 of the branched side chains R are each bonded to the same carbon atom 2308 in the fused atomic rings 2304, and each of the branched side chains R in the pair 2306 extend on opposite sides of the plane P at an angle Φ in a range of 60-90 degrees with respect to the plane P. As illustrated herein, the branched side chains R can be oriented and the branching point 100 can be positioned away from the backbone 2202 and along the side chain 2204 so as to increase mobility of the lyotropic semiconducting polymers 2302 by a factor of at least 100.

In one method, the lyotropic semiconducting polymers 2302 are prepared so as to each have a backbone and a side chain attached to the backbone, wherein the side chain includes a branched chain having a branching point positioned further along the side chain so as to reduce the pi-pi stacking distance between the lyotropic semiconducting polymers. In some examples, positioning of the branching point 100 away from the backbone 2202 and along the side chain 2204 reduces a pi stacking distance D between the lyotropic semiconducting polymers 2302 by at least 0.25 Å (e.g., the pi-pi stacking distance D is reduced by 0.25 Å as compared to the pi stacking distance using an unbranched side chain). In other examples, the branching point 100 is positioned so that a pi-pi stacking distance D between the lyotropic semiconducting polymers 2302 is less than 3.7 Angstroms or in a range of 3.5-3.8 Angstroms.

FIGS. 1A-1E, 22A-22B, and 23 further illustrate examples wherein the branching point 100 is at a position 104 along the side chain 2204 between 2 and 20 atoms from the backbone 2202. In some examples, the atom 104 on the side chain 2204 at the branching point 100 is carbon or a heteroatom that is at least trivalent.

FIGS. 1A-1E further illustrate examples wherein the side chain R has the structure

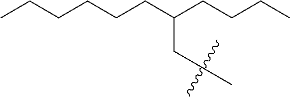 [SMILES: *CC(CCCC)CCCCCC]

(referred to herein as C1-BO)

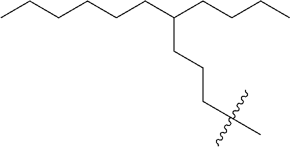 [SMILES: *CCCC(CCCC)CCCCCC]

(referred to herein as C3-BO)

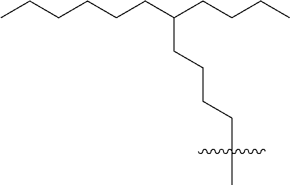 [SMILES: *CCCCC(CCCC)CCCCCC]

(referred to herein as C4-BO)

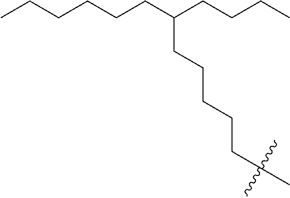 [SMILES: *CCCCCC(CCCC)CCCCCC]

(referred to herein as C5-BO)

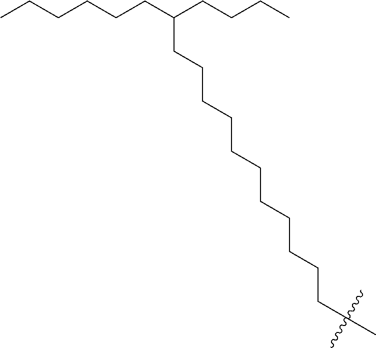 [SMILES: *CCCCCCCCCCCC(CCCC)CCCCCC]

(referred to herein as C11-BO).

FIGS. 1A-1E illustrate the location 108 of carbon atom in the backbone 2202 that is connected/bonded to the side chain R.

Although FIG. 23 illustrates the backbone comprises a donor-acceptor copolymer backbone, other semiconductor polymers (e.g., donor-donor polymers) are possible as illustrated herein. Moreover, the lyotropic semiconducting polymers may comprise a variety of compositions including fused aromatic rings and/or fluorine and/or fluorinated polymers.

### Advantages and Improvements

Liquid crystalline materials allow for control over molecular orientation, a desirable property for polymer electronics. Current lyotropic liquid crystalline materials that can be used for polymer electronics necessitate solubilizing side chains which disrupt molecular packing, resulting in poor charge carrier mobility.

The present disclosure, on the other hand, reports on the unexpected and surprising discovery that changing the structure of the side chain (moving the branch point further from the conjugated backbone) allows for control over the molecular packing (making the distance between molecules closer, as illustrated by GIWAXS) while retaining the lyotropic liquid crystalline behavior (as observed by UV-vis and POM). Thus, unexpectedly, amphiphilicity is retained, the polymers exhibit temperature and solvent dependent self assembly in solution, and π-stacking distance is reduced. This closer packing improves/increases the charge carrier mobility in transistors as compared to the transistors using current state of the art lyotropic liquid crystalline conjugated polymers. In one or more examples, the mobility of transistors according to the present invention reaches a mobility (for the un-aligned case) of 0.41 cm²V⁻¹s⁻¹. Shear aligning the liquid crystals may further enhance the mobility.

### REFERENCES

The following references are incorporated by reference herein.

(1) Lagerwall, J.; Scalia, G.; Haluska, M.; Dettlaff-Weglikowska, U.; Roth, S.; Giesselmann, F. Nanotube Alignment Using Lyotropic Liquid Crystals. Adv. Mater. 2007, 19 (3), 359-364.

(2) Madsen, L. A.; Dingemans, T. J.; Nakata, M.; Samulski, E. T. Thermotropic Biaxial Nematic Liquid Crystals. Phys. Rev. Lett. 2004, 92 (14), 145505-145510.

(3) Jeong, J.; Han, G.; Johnson, A. T. C.; Collings, P. J.; Lubensky, T. C.; Yodh, A. G. Homeotropic Alignment of Lyotropic Chrotnonic Liquid Crystals Using Noncovalent Interactions. Langmuir 2014, 30 (10), 2914-2920.

(4) Geary, J. M.; Goodby, J. W.; Kmetz, A. R.; Patel, J. S. The Mechanism of Polymer Alignment of Liquid-Crystal Materials. J. Appl. Phys. 1987, 62 (10), 4100-4108.

(5) Stöhr, J.; Samant, M. G. Liquid Crystal Alignment by Rubbed Polymer Surfaces: a Microscopic Bond Orientation Model. J. Electron Spectrosc. Relat. Phenom. 1999, 99, 189-207.

(6) Jones, L. P. Alignment Properties of Liquid Crystals. In Handbook of Visual Display Technology, Chen, J., Cranton, W., Fihn, M., Eds.; Springer-Verlag: Berlin Heidelberg, 2012; Chapter 7, pp 1388-1401.

(7) Tao, Y.; Zohar, H.; Olsen, B. D.; Segalman, R. A. Hierarchical Nanostructure Control in Rod-Coil Block Copolymers with Magnetic Fields. Nano Lett. 2007, 7 (9), 2742-2746.

(8) Coropceanu, V.; Cornil, J.; da Silva Filho, D. A.; Olivier, Y.; Silbey, R.;Bredas, J.-L. Charge Transportin Organic Semiconductors. Chem. Rev. 2007, 107 (4), 926-952.

(9) Tseng, H.-R.; Phan, H.; Luo, C.; Wang, M.; Perez, L. A.; Patel, S. N.; Ying, L.; Kramer, E. J.; Nguyen, T.-Q.; Bazan, G. C.; Heeger, A. J. High-Mobility Field-Effect Transistors Fabricated with Macroscopic Aligned Semiconducting Polymers. Adv. Mater. 2014, 26 (19), 2993-2998.

(10) Luo, C.; Kyaw, A. K. K.; Perez, L. A.; Patel, S.; Wang, M.; Grimm, B,; Bazan, G. C.; Kramer, E. J.; Heeger, A. J. General Strategy for Self-Assembly of Highly Oriented Nanocrystalline Semiconducting Polymers with High Mobility. Nano Lett. 2014, 14 (5), 2764-2771.

(11) Boudouris, B. W.; Ho, V.; Jimison, L. H.; Toney, M. F.; Salleo, A.; Segalman, R. A. Real-Time Observation of Poly(3-alkylthiophene) Crystallization and Correlation with Transient Optoelectronic Proper-ties. Macromolecules 2011, 44 (17), 6653-6658.

(12) Duong, D. T.; Ho, V.; Shang, Z.; Mollinger, S.; Mannsfeld, S. C. B.; Dacuña, J.; Toney, M. F.; Segalman, R.; Salleo, A. Mechanism of Crystallization and Implications for Charge Transport in Poly(3-ethylhexylthiophene) Thin Films. Adv. Funct. Mater. 2014, 24 (28), 4515-4521.

(13) Kline, R. J.; McGehee, M. D.; Kadnikova, E. N.; Liu, J.; Frećhet, J. M. J.; Toney, M. F. Dependence of Regioregular Poly(3-hexylthiophene) Film Morphology and Field-Effect Mobility on Molecular Weight. Macromolecules 2005, 38 (8), 3312-3319.

(14) Jimison, L. H.; Toney, M. F.; McCulloch, I.; Heeney, M.; Salleo, A. Charge-Transport Anisotropy Due to Grain Boundaries in Directionally Crystallized Thin Films of Regioregular Poly(3-hexylthiophene). Adv. Mater. 2009, 21 (16), 1568-1572.

(15) Vangerven, T.; Verstappen, P.; Drijkoningen, J.; Dierckx, W.; Himmelberger, S.; Salleo, A.; Vanderzande, D.; Maes, W.; Manca, J. V. Molar Mass versus Polymer Solar Cell Performance: Highlighting the Role of Homocouplings. Chem. Mater. 2015, 27 (10), 3726-3733.

(16) Steyrleuthner, R.; Di Pietro, R.; Collins, B. A.; Polzer, F.; Himmelberger, S.; Schubert, M.; Chen, Z.; Zhang, S.; Salleo, A.; Ade, H.; Facchetti, A.; Neher, D. The Role of Regioregularity, Crystallinity, and Chain Orientation on Electron Transport in a High-Mobility n-Type Copolymer. J. Am. Chem. Soc. 2014, 136 (11), 4245-4256.

(17) Himmelberger, S.; Vandewal, K.; Fei, Z.; Heeney, M.; Salleo, A. Role of Molecular Weight Distribution on Charge Transport in Semiconducting Polymers. Macromolecules 2014, 47 (20), 7151-7157.

(18) Himmelberger, S.; Salleo, A. Engineering semiconducting polymers for efficient charge transport. MRS Commun. 2015, 5 (3), 383-395.

(19) Tsao, H. N.; Cho, D.; Andreasen, J. W.; Rouhanipour, A.; Breiby, D. W.; Pisula, W.; Mullen, K. The Influence of Morphology on High-Performance Polymer Field-Effect Transistors. Adv. Mater. 2009, 21 (2), 209-212.

(20) Zen, A.; Pflaum, J.; Hirschmann, S.; Zhuang, W.; Jaiser, F.; Asawapirom, U.; Rabe, J. P.; Scherf, U.; Neher, D. Effect of Molecular Weight and Annealing of Poly(3-hexylthiophene)s on the Performance of Organic Field-Effect Transistors. Adv. Funct. Mater. 2004, 14 (8), 757-764.

(21) Olivier, Y.; Niedzialek, D.; Lemaur, V.; Pisula, W.; Müllen, K.; Koldemir, U.; Reynolds, J. R.; Lazzaroni, R.; Cornil, J.; Beljonne, D. 25th Anniversary Article: High-Mobility Hole and Electron Transport Conjugated Polymers: How Structure Defines Function. Adv. Mater. 2014, 26 (14), 2119-2136.

(22) Yan, H.; Song, Y.; McKeown, G. R.; Scholes, G. D.; Seferos, D. S. Adding Amorphous Content to Highly Crystalline Polymer Nanowire Solar Cells Increases Performance. Adv. Mater. 2015, 27 (23), 3484-3491.

(23) Bridges, C. R.; Ford, M. J.; Popere, B. C.; Bazan, G. C.; Segalman, R. A. Formation and Structure of Lyotropic Liquid Crystalline Mesophases in Donor-Acceptor Semiconducting Polymers. Macromolecules 2016, 49 (19), 7220-7229.

(24) Bridges, C. R.; Ford, M. J.; Bazan, G. C.; Segalman, R. A. Molecular Considerations for Mesophase Interaction and Alignment of Lyotropic Liquid Crystalline Semiconducting Polymers. ACS Macro Lett. 2017, 619-624.

(25) Wang, M.; Ford, M.; Phan, H.; Coughlin, J.; Nguyen, T.-Q.; Bazan, G. C. Chem. Commun. 2016 Wang. Chemical Communications 2016, 52, 3207-3210.

(26) Wang, M.; Wang, H.; Ford, M.; Yuan, J.; Mai, C.-K.; Fronk, S.; Bazan, G. C. Materials Chemistry A. Journal of Materials Chemistry A: Materials for energy and sustainability 2016, 00, 1-8.

(27) Ying, L.; Hsu, B. B. Y.; Zhan, H.; Welch, G. C.; Zalar, P.; Perez, L. A.; Kramer, E. J.; Nguyen, T.-Q.; Heeger, A. J.; Wong, W.-Y.; Bazan, G. C. Regioregular Pyridal[2,1,3]Thiadiazole II-Conjugated Copolymers. J. Am. Chem. Soc. 2011, 133 (46), 18538-18541.

(28) Hinkel, F.; Marszalek, T.; Zajaczkowski, W.; Puniredd, S. R.; Baumgarten, M.; Pisula, W.; Müllen, K. Tuning Packing and Solubility of Donor (D)-Acceptor (A) Polymers by cis-trans Isomerization within Alkenyl Side Chains. Chem. Mater. 2014, 26 (16), 4844-4848.

(29) Kim, Y.; Cook, S.; Tuladhar, S. M.; Choulis, S. A.; Nelson, J.; Durrant, J. R.; Bradley, D. D. C.; Giles, M.; McCulloch, I.; Ha, C.-S.; Ree, M. A strong regioregularity effect in self-organizing conjugated polymer films and high-efficiency polythiophene:fullerene solar cells. Nat. Mater. 2006, 5 (3), 197-203.

(30) Prosa, T. J.; Winokur, M. J.; Moulton, J.; Smith, P.; Heeger, A. J. X-ray Structural Studies of Poly(3-alkylthiophenes): An Example of an Inverse Comb. Macromolecules 1992, 25 (17), 4364-4372.

(31) Chen, T. A.; Wu, X.; Rieke, R. D. Regiocontrolled Synthesis of Poly(3-alkylthiophenes) Mediated by Rieke Zinc: Their Characterization and Solid-state Properties. J. Am. Chem. Soc. 1995, 117 (1), 233-244.

(32) Prosa, T. J.; Winokur, M. J.; McCullough, R. D. Evidence of a Novel Side Chain Structure in Regioregular Poly(3-alkylthiophenes). Macromolecules 1996, 29 (46), 3654-3656.

(33) Meille, S. V.; Romita, V.; Caronna, T.; Lovinger, A. J.; Catellani, M.; Belobrzeckaja, L. Influence of Molecular Weight and Regioregularity on the Polymorphic Behavior of Poly(3-decylthiophenes). Macromolecules 1997, 30 (25), 7898-7905.

(34) Beaujuge, P. M.; Pisula, W.; Tsao, H. N.; Ellinger, S.; Müllen, K.; Reynolds, J. R. Tailoring Structure-Property Relationships in Dithienosilole-Benzothiadiazole Donor-Acceptor Copolymers. J. Am. Chem. Soc. 2009, 131 (22), 7514-7515.

(35) Huang, Y.; Guo, X.; Liu, F.; Huo, L.; Chen, Y.; Russell, T. P.; Han, C. C.; Li, Y.; Hou, J. Improving the Ordering and Photovoltaic Properties by Extending π-Conjugated Area of Electron-Donating Units in Polymers with D-A Structure. Adv. Mater. 2012, 24 (25), 3383-3389.

(36) Ford, M. J.; Wang, M.; Patel, S. N.; Phan, H.; Segalman, R. A.; Nguyen, T.-Q.; Bazan, G. C. High Mobility Organic Field-Effect Transistors from Majority Insulator Blends. Chem. Mater. 2016, 28 (5), 1256-1260.

(37) Duong, D. T.; Toney, M. F.; Salleo, A. Role of confinement and aggregation in charge transport in semicrystalline polythiophene thin films. Phys. Rev. B: Condens. Matter Mater. Phys. 2012, 86 (20), 205205.

(38) Fischer, F. S. U.; Kayunkid, N.; Trefz, D.; Ludwigs, S.; Brinkmann, M. Structural Models of Poly(Cyclopentadithiophene-Alt-Benzothiadiazole) with Branched Side Chains: Impact of a Single Fluorine Atom on the Crystal Structure and Polymorphism of a Conjugated Polymer. Macromolecules 2015, 48 (12), 3974-3982.

(39) Fischer, F. S. U.; Trefz, D.; Back, J.; Kayunkid, N.; Tornow, B.; Albrecht, S.; Yager, K. G.; Singh, G.; Karim, A.; Neher, D.; Brinkmann, M.; Ludwigs, S. Highly Crystalline Films of PCPDTBT with Branched Side Chains by Solvent Vapor Crystallization: Influence on Opto-Electronic Properties. Adv. Mater. 2014, 27 (7), 1223-1228.

(40) Lincker, F.; Delbosc, N.; Bailly, S.; De Bettignies, R.; Billon, M.; Pron, A.; Demadrille, R. Fluorenone-Based Molecules for Bulk-Heterojunction Solar Cells: Synthesis, Characterization, and Photo-voltaic Properties. Adv. Funct. Mater. 2008, 18 (21), 3444-3453.

(41) Sun, Y.; Chien, S.-C.; Yip, H.-L.; Zhang, Y.; Chen, K.-S.; Zeigler, D. F.; Chen, F.-C.; Lin, B.; Jen, A. K. Y. High-mobility low-bandgap conjugated copolymers based on indacenodithiophene and thiadiazolo[3,4-c]pyridine units for thin film transistor and photo-voltaic applications. J. Mater. Chem. 2011, 21 (35), 13247-13255.

(42) Love, B. E.; Jones, E. G. The Use of Salicylaldehyde Phenylhydrazone as an Indicator for the Titration of Organometallic Reagents. J. Org. Chem. 1999, 64 (10), 3755-3756.

(44) Fu, B.; Baltazar, J.; Sankar, A. R.; Chu, P.-H.; Zhang, S.; Collard, D. M.; Reichmanis, E. Enhancing Field-Effect Mobility of Conjugated Polymers Through Rational Design of Branched Side Chains. Adv. Funct. Mater. 2014, 24 (24), 3734-3744)

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A composition of matter, comprising:
lyotropic semiconducting polymers each having a backbone and a side chain attached to the backbone, wherein:
the side chain includes a branched chain having a branching point positioned more than one atom from the backbone and along the side chain, and
the branching point is the first or closest branching point to the backbone.

2. The composition of matter of claim 1, wherein the branching point is at a position along the side chain between 2 and 20 atoms from the backbone.

3. The composition of matter of claim 1, wherein the atom on the side chain at the branching point is carbon or a heteroatom that is at least trivalent.

4. The composition of matter of claim 1, further comprising:
a lyotropic solution including the lyotropic semiconducting polymers aligned in a liquid crystal.

5. The composition of matter of claim 1, wherein the backbone comprises a donor-acceptor copolymer backbone including fused aromatic rings and fluorine.

6. The composition of matter claim 1, wherein:
the branched side chains disrupt pi stacking between the lyotropic semiconducting polymers, and
the branched side chains extend outside a plane containing the fused aromatic rings.

7. The composition of matter of claim 6, further comprising:
a pair of branched sidechains each bonded to the same carbon atom in the fused atomic rings, and
each of the branched side chains in the pair extending on opposite sides of the plane at an angle in a range of 60-90 degrees with respect to the plane.

8. The composition of matter of claim 6, wherein:
the branched side chains are oriented so as to disrupt pi stacking between the lyotropic semiconducting polymers, and
positioning the branching point away from the backbone and along the side chain increases mobility of the lyotropic semiconducting polymer by a factor of at least 100.

9. The composition of matter of claim 6, wherein positioning the branching point away from the backbone and along the side chain reduces a pi stacking distance between the lyotropic semiconducting polymers by at least 0.25 Å.

10. The composition of matter of claim 1, wherein:
the semiconducting polymers are amphiphilic semiconducting polymers, and
the side chains dissolve in a solvent more effectively than the backbone.

11. The composition of matter of claim 9, wherein the solvent comprises at least one compound selected from an alkane, an alkene, an alkyne, an ether, an ester, an alcohol, a halide, an aldehyde, a ketone, an amine, an amide, and water.

12. The composition of matter of claim 1, wherein the side chain is a branched C₅-C₅₀ alkyl chain.

13. The composition of matter of claim 1, wherein the backbone has a repeat unit that comprises:
an acceptor of the structure: 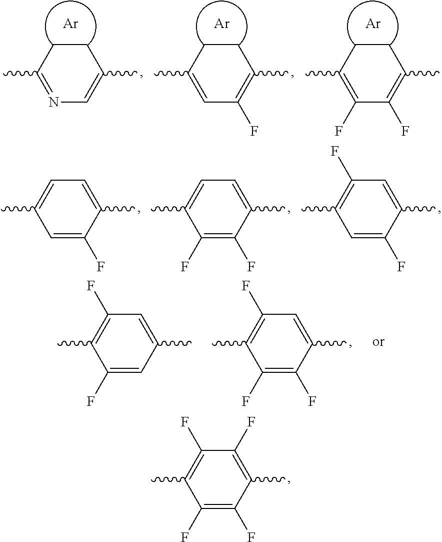
wherein Ar is a substituted or non-substituted aromatic functional group, or Ar is nothing and the valence of the pyridine ring or fluorinated ring is completed with hydrogen; and
a donor of the structure: 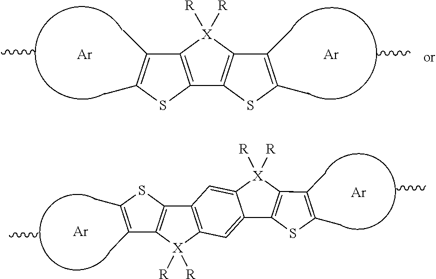
wherein each Ar is independently a substituted or non-substituted aromatic functional group, or each Ar is independently nothing and the valence of its respective thiophene ring is completed with hydrogen,
each R is independently hydrogen or a substituted or non-substituted alkyl, aryl or alkoxy chain;
or each R is a branched side chain having a branching point positioned more than one carbon atom from the backbone and along the side chain,
and
X is C, C═C, Si, Ge, N or P.

14. The composition of matter of claim 1, wherein the lyotropic semiconducting polymers each have the structure: 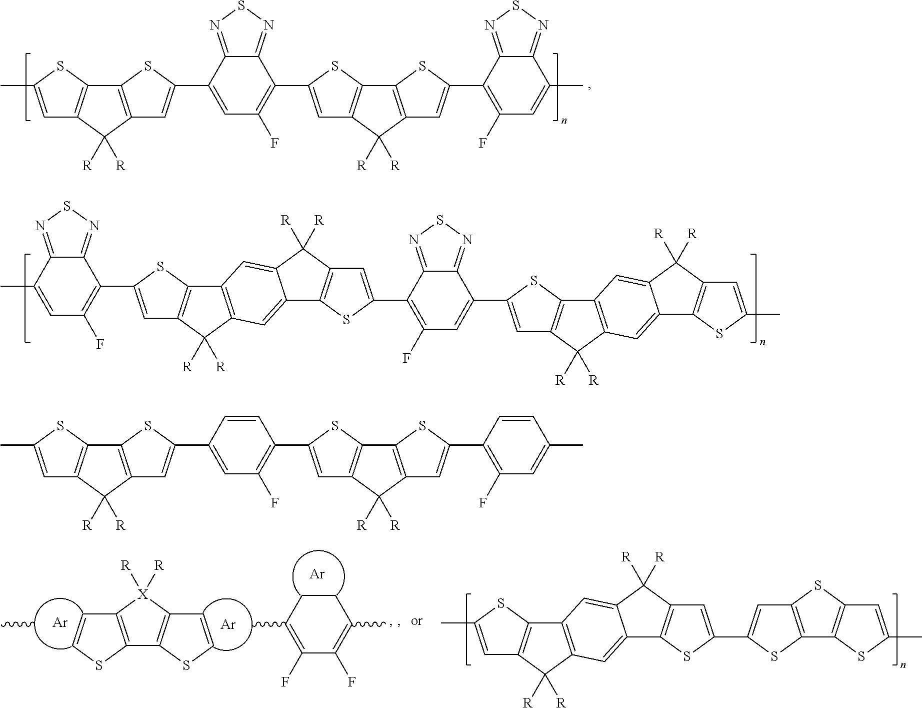
wherein R is a branched alkyl, aryl or alkoxy chain and n is an integer.

15. The composition of claim 13, wherein the side chain is a branched C₅-C₅₀ alkyl chain.

16. The composition of claim 13, wherein R is C1-BO, C3-BO, C4-BO, C5-BO, or C11-BO.

17. The composition of claim 13, wherein R is 2 (or 1 or 3, or 4)-butyloctyl, 4 (or 1, or 2, or 3, or 5, or 6)-butyldecyl, 5 (or 1, or 2, or 3, or 4, or 6, or 7)-butylundecyl, 6 (or 1, or 2, or 3, or 4, or 5, or 7, or 8)-butyldodecyl, 12 (or 1, or 2, or 3, or 4, or 5, or 6, or 7, or 8, or 9, or 10, or 11, or 13, or 14)-butyloctadecyl.

18. The composition of claim 13, wherein the branching point is at a position along the side chain between 2 and 20 atoms from the backbone.

19. An organic device comprising the composition of matter of claim 13.

20. A transistor comprising a channel including the composition of matter of claim 1.

21. The transistor of claim 20, wherein the lyotropic semiconducting polymers are disposed on, and aligned with, grooves on a dielectric layer.

22. The transistor of claim 21, wherein the dielectric layer comprises polyimide having a thickness between 25 nm and 200 nm.

23. The composition of matter of claim 1, wherein the branching point is positioned so that a pi-pi stacking distance between the lyotropic semiconducting polymers is less than 3.7 Angstroms or in a range of 3.5-3.8 Angstroms.

24. A method of fabricating a composition of matter, comprising:
preparing lyotropic semiconducting polymers each having a backbone and a side chain attached to the backbone, wherein the side chain includes a branched chain having a branching point positioned further along the side chain so as to reduce the pi-pi stacking distance between the lyotropic semiconducting polymers.

25. A composition of matter, comprising:
lyotropic semiconducting polymers each having a donor-acceptor copolymer backbone and a side chain attached to the backbone, wherein the side chain includes a branched chain having a branching point positioned so that a pi-pi stacking distance between the lyotropic semiconducting polymers is less than 3.7 Angstroms or in a range of 3.5-3.8 Angstroms.
